(19) United States
(12) Patent Application Publication
(10) Pub. No.: US 2025/0015168 A1
(43) Pub. Date: Jan. 9, 2025

(54) SEMICONDUCTOR DEVICE AND METHOD FOR MANUFACTURING SEMICONDUCTOR DEVICE

(71) Applicant: Japan Display Inc., Tokyo (JP)

(72) Inventors: Takaya TAMARU, Tokyo (JP); Masashi TSUBUKU, Tokyo (JP); Hajime WATAKABE, Tokyo (JP); Toshinari SASAKI, Tokyo (JP)

(73) Assignee: Japan Display Inc., Tokyo (JP)

(21) Appl. No.: 18/894,340

(22) Filed: Sep. 24, 2024

Related U.S. Application Data
(63) Continuation of application No. PCT/JP2023/009876, filed on Mar. 14, 2023.

(30) Foreign Application Priority Data
Mar. 30, 2022 (JP) 2022-057450

(51) Int. Cl. H01L 29/66; G02F 1/1368; H01L 21/02; H01L 29/786; H10K 59/121

(52) U.S. Cl. CPC H01L 29/66969; H01L 21/02565; H01L 29/78633; H01L 29/78648; H01L 29/7869; H01L 29/78696; G02F 1/1368; H10K 59/1213

(57) ABSTRACT

A method for manufacturing a semiconductor device, the method comprising steps of: forming a first metal oxide layer containing aluminium as a main component above an insulating surface; performing a planarization process on a surface of the first metal oxide layer; forming an oxide semiconductor layer on the insulating surface on which the planarization process is performed; forming a gate insulating layer above the oxide semiconductor layer; and forming a gate electrode facing the oxide semiconductor layer above the gate insulating layer.

### CROSS REFERENCE TO RELATED APPLICATIONS

This application is a Continuation of International Patent Application No. PCT/JP2023/009876, filed on Mar. 14, 2023, which claims the benefit of priority to Japanese Patent Application No. 2022-057450, filed on Mar. 30, 2022, the entire contents of which are incorporated herein by reference.

### FIELD

An embodiment of the present invention relates to a semiconductor device and a method for manufacturing a semiconductor device. In particular, an embodiment of the present invention relates to a semiconductor device and a method for manufacturing a semiconductor device in which an oxide semiconductor is used as a channel.

### BACKGROUND

In recent years, a semiconductor device in which an oxide semiconductor is used for a channel instead of amorphous silicon, low-temperature polysilicon, and single-crystal silicon has been developed (for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device in which the oxide semiconductor is used for the channel can be formed with a simple structure and a low-temperature process, similar to a semiconductor device in which amorphous silicon is used as a channel. The semiconductor device in which the oxide semiconductor is used for the channel is known to have higher mobility than the semiconductor device in which amorphous silicon is used for the channel.

It is essential to supply oxygen to an oxide semiconductor layer in the manufacturing process and to reduce oxygen deficiencies formed in the oxide semiconductor layer in order for the semiconductor device in which the oxide semiconductor is used for the channel to perform a stable operation. For example, a technique of forming an insulating layer covering the oxide semiconductor layer under the condition that the insulating layer contains more oxygen is disclosed as one method of supplying oxygen to the oxide semiconductor layer.

### SUMMARY

A method for manufacturing a semiconductor device according to an embodiment of the present invention includes forming a first metal oxide layer containing aluminium as a main component above an insulating surface, performing a planarization process on a surface of the first metal oxide layer, forming an oxide semiconductor layer on the insulating surface on which the planarization process was performed, forming a gate insulating layer above the oxide semiconductor layer, and forming a gate electrode facing the oxide semiconductor layer above the gate insulating layer.

A semiconductor device according to an embodiment of the present invention includes a metal oxide layer containing aluminium as a main component above an insulating surface, an oxide semiconductor layer on the metal oxide layer, a gate electrode facing the oxide semiconductor layer, and a gate insulating layer between the oxide semiconductor layer and the gate electrode, wherein a relationship between an arithmetic mean roughness Ra (nm) of a surface of the metal oxide layer and a field effect mobility μ (cm²/Vs) is expressed by the following formula.

μ=−10.033Ra+48.23

(Where, the arithmetic mean roughness Ra≤0.80 nm)

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a sequence diagram showing a method for manufacturing a semiconductor device according to a modification of an embodiment of the present invention.

FIG. 15 is a cross-sectional view showing a method for manufacturing a semiconductor device according to a modification of an embodiment of the present invention.

FIG. 16 is a cross-sectional view showing a method for manufacturing a semiconductor device according to a modification of an embodiment of the present invention.

FIG. 17 is a cross-sectional view showing an outline of a semiconductor device according to a modification of an embodiment of the present invention.

FIG. 18 is a sequence diagram showing a method for manufacturing a semiconductor device according to a modification of an embodiment of the present invention.

FIG. 19 is a cross-sectional view showing an outline of a semiconductor device according to a modification of an embodiment of the present invention.

FIG. 20 is a plan view showing an outline of a semiconductor device according to a modification of an embodiment of the present invention.

FIG. 21 is a sequence diagram showing a method for manufacturing a semiconductor device according to a modification of an embodiment of the present invention.

FIG. 22 is a cross-sectional view showing a method for manufacturing a semiconductor device according to a modification of an embodiment of the present invention.

FIG. 23 is a cross-sectional view showing a method for manufacturing a semiconductor device according to an embodiment of the present invention.

FIG. 24 is a sequence diagram showing a method for manufacturing a semiconductor device according to a modification of an embodiment of the present invention.

FIG. 25 is a cross-sectional view showing a method for manufacturing a semiconductor device according to an embodiment of the present invention.

FIG. 26 is a cross-sectional view showing a method for manufacturing a semiconductor device according to an embodiment of the present invention.

FIG. 27 is a cross-sectional view showing a method for manufacturing a semiconductor device according to an embodiment of the present invention.

FIG. 28 is a cross-sectional view showing a method for manufacturing a semiconductor device according to an embodiment of the present invention.

FIG. 29 is a cross-sectional view showing a method for manufacturing a semiconductor device according to an embodiment of the present invention.

FIG. 30 is a cross-sectional view showing a method for manufacturing a semiconductor device according to an embodiment of the present invention.

FIG. 31 is a cross-sectional view showing a method for manufacturing a semiconductor device according to an embodiment of the present invention.

FIG. 32 is a cross-sectional view showing a method for manufacturing a semiconductor device according to an embodiment of the present invention.

FIG. 33 is a cross-sectional view showing a method for manufacturing a semiconductor device according to an embodiment of the present invention.

FIG. 34 is a cross-sectional view showing a method for manufacturing a semiconductor device according to an embodiment of the present invention.

FIG. 35 is a cross-sectional view showing a method for manufacturing a semiconductor device according to an embodiment of the present invention.

FIG. 36 is a plan view showing an outline of a display device according to an embodiment of the present invention.

FIG. 37 is a block diagram showing a circuit configuration of a display device according to an embodiment of the present invention.

FIG. 38 is a circuit diagram showing a pixel circuit of a display device according to an embodiment of the present invention.

FIG. 39 is a cross-sectional view showing an outline of a display device according to an embodiment of the present invention.

FIG. 40 is a plan view of a pixel electrode and a common electrode of a display device according to an embodiment of the present invention.

FIG. 41 is a circuit diagram showing a pixel circuit of a display device according to an embodiment of the present invention.

FIG. 42 is a cross-sectional view showing an outline of a display device according to an embodiment of the present invention.

FIG. 43 is a diagram showing the electrical characteristics of a semiconductor device according to an embodiment of the present invention.

FIG. 44 is a diagram showing the electrical characteristics of a semiconductor device according to an embodiment of the present invention.

FIG. 45 is a diagram showing the electrical characteristics of a semiconductor device according to an embodiment of the present invention.

FIG. 46 is a diagram showing the electrical characteristics of a semiconductor device according to an embodiment of the present invention.

FIG. 47 shows a boxplot of a variation in field-effect mobility of a semiconductor device according to an embodiment of the present invention.

FIG. 48 is a diagram showing the electrical characteristics of a semiconductor device according to an embodiment of the present invention.

FIG. 49 is a diagram showing the electrical characteristics of a semiconductor device according to an embodiment of the present invention.

FIG. 50 is a diagram showing the electrical characteristics of a semiconductor device according to an embodiment of the present invention.

FIG. 51 is a boxplot of a variation in field-effect mobility of a semiconductor device according to an embodiment of the present invention.

FIG. 52A is an AFM observation image of an aluminum oxide layer by a planarization process (Condition 1).

FIG. 52B is an AFM observation image of an aluminum oxide layer by a planarization process (Condition 2).

FIG. 53 shows a dependence of an arithmetic mean roughness (Ra) of an aluminum oxide layer by a planarization process (Condition 1) and field-effect mobility of a semiconductor device.

FIG. 54 shows a dependence of an arithmetic mean roughness (Ra) of an aluminum oxide layer by a planarization process (Condition 2) and field-effect mobility of a semiconductor device.

FIG. 55 shows a dependence of an arithmetic mean roughness (Ra) of an aluminum oxide layer by a planarization process (conditions 1 and 2) and field effect mobility of a semiconductor device.

### DESCRIPTION OF EMBODIMENTS

The insulating layer formed with more oxygen-containing conditions contains more defects. As a result, abnormal characteristics of the semiconductor device or a variation in characteristics in a reliability test occur, which are considered to be caused by electrons becoming trapped in the defect. On the other hand, if an insulating layer with fewer defects is used, oxygen in the insulating layer cannot be increased. Therefore, sufficient oxygen cannot be supplied from the insulating layer to the oxide semiconductor layer. As described above, there is a demand for realizing a structure capable of repairing oxygen deficiencies formed in the oxide semiconductor layer while reducing defects in the insulating layer that cause the variation in characteristics of the semiconductor device.

Further, a semiconductor device with high mobility can be obtained by relatively increasing a ratio of indium contained in the oxide semiconductor layer. However, if the ratio of indium contained in the oxide semiconductor layer is high, oxygen deficiencies are likely to be formed in the oxide semiconductor layer. Therefore, in order to realize high mobility while maintaining high reliability, it is necessary to devise a configuration of the insulating layer around the oxide semiconductor layer.

An object of the embodiment of the present invention is to realize a highly reliable semiconductor device having high mobility.

Embodiments of the present invention will be described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

“Semiconductor device” refers to all devices that can function by utilizing semiconductor characteristics. Transistors and semiconductor circuits are a form of semiconductor device. For example, a semiconductor device may be used in an integrated circuit (IC) such as a micro-processing unit (MPU) or a memory circuit in addition to a transistor used in a display device.

“Display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later will be described by exemplifying the liquid crystal display device including a liquid crystal layer and an organic EL display device including an organic EL layer as the display device, the structure in the present embodiment can be applied to a display device including the other electro-optic layers described above.

In the embodiments of the present invention, a direction from a substrate to an oxide semiconductor layer is referred to as “on” or “above”. Reversely, a direction from the oxide semiconductor layer to the substrate is referred to as “under” or “below”. As described above, for convenience of explanation, although the phrase “above (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. Above or below means a stacking order in a structure in which multiple layers are stacked, and when it is expressed as a pixel electrode above a transistor, it may be a positional relationship where the transistor and the pixel electrode do not overlap each other in a plan view. On the other hand, when it is expressed as a pixel electrode vertically above a transistor, it means a positional relationship where the transistor and the pixel electrode overlap each other in a plan view.

The expressions “α includes A, B, or C”, “α includes any of A, B, and C”, and “α includes one selected from a group consisting of A, B, and C” do not exclude the case where α includes multiple combinations of A to C unless otherwise specified. Furthermore, these expressions do not exclude the case where α includes other elements.

In addition, the following embodiments may be combined with each other as long as there is no technical contradiction.

### First Embodiment

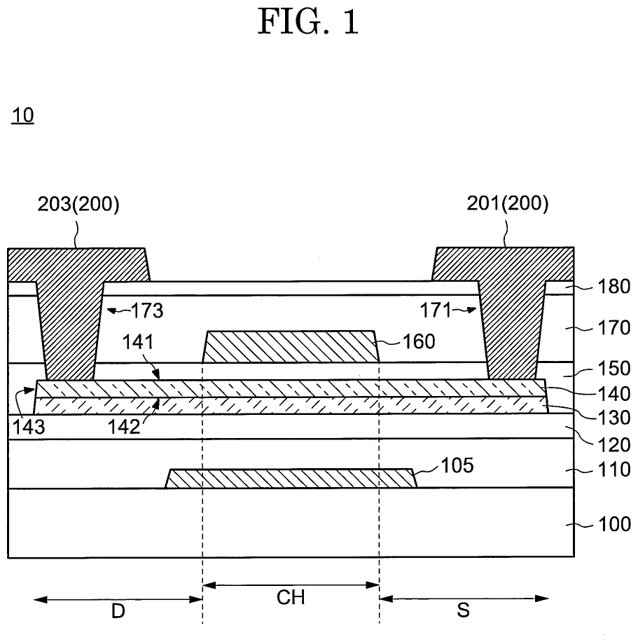

A semiconductor device according to an embodiment of the present invention will be described with reference to FIG. 1 to FIG. 13.

### Configuration of Semiconductor Device 10

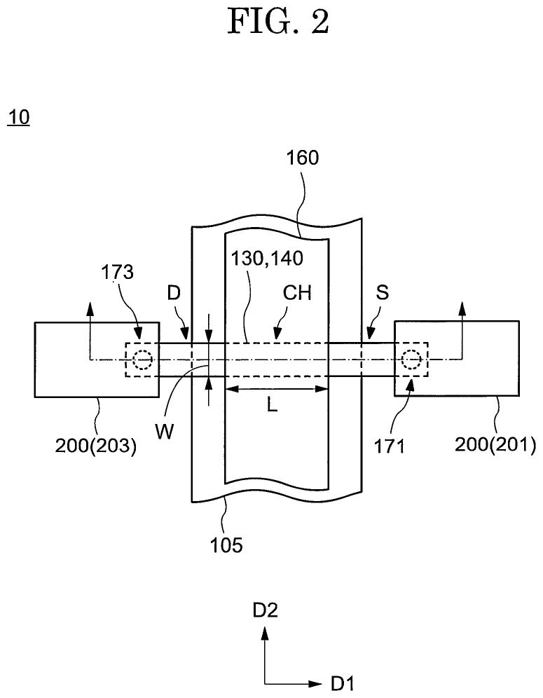

A configuration of a semiconductor device 10 according to an embodiment of the present invention will be described with reference to FIG. 1 and FIG. 2. FIG. 1 is a cross-sectional view showing an outline of a semiconductor device according to an embodiment of the present invention. FIG. 2 is a plan view showing an outline of a semiconductor device according to an embodiment of the present invention.

As shown in FIG. 1, the semiconductor device 10 is arranged above a substrate 100. The semiconductor device 10 includes a gate electrode 105, gate insulating layers 110 and 120, a metal oxide layer 130, an oxide semiconductor layer 140, a gate insulating layer 150, a gate electrode 160, insulating layers 170 and 180, a source electrode 201, and a drain electrode 203. If the source electrode 201 and the drain electrode 203 are not specifically distinguished from each other, they may be referred to as a source-drain electrode 200.

The gate electrode 105 is arranged above the substrate 100. The gate insulating layer 110 and the gate insulating layer 120 are arranged above the substrate 100 and the gate electrode 105. The metal oxide layer 130 is arranged above the gate insulating layer 120. The metal oxide layer 130 is in contact with the gate insulating layer 120. The oxide semiconductor layer 140 is arranged above the metal oxide layer 130. The oxide semiconductor layer 140 is in contact with the metal oxide layer 130. In the main surface of the oxide semiconductor layer 140, a surface in contact with the metal oxide layer 130 is referred to as a lower surface 142. An end portion of the metal oxide layer 130 substantially coincides with an end portion of the oxide semiconductor layer 140.

In the present embodiment, no semiconductor layer or oxide semiconductor layer is arranged between the metal oxide layer 130 and the substrate 100.

In the present embodiment, although a configuration in which the metal oxide layer 130 is in contact with the gate insulating layer 120 and the oxide semiconductor layer 140 is in contact with the metal oxide layer 130 is exemplified, the configuration is not limited to this configuration. Other layers may be arranged between the gate insulating layer 120 and the metal oxide layer 130. Other layers may also be arranged between the metal oxide layer 130 and the oxide semiconductor layer 140.

In FIG. 1, although sidewalls of the metal oxide layer 130 and sidewalls of the oxide semiconductor layer 140 are arranged in a straight line, the configuration is not limited to this configuration. An angle of the sidewall of the metal oxide layer 130 with respect to the main surface of the substrate 100 may be different from an angle of the sidewall of the oxide semiconductor layer 140 with respect to the main surface. The cross-sectional shapes of the side wall of at least one of the metal oxide layer 130 and the oxide semiconductor layer 140 may be curved.

The gate electrode 160 faces the oxide semiconductor layer 140. The gate insulating layer 150 is arranged between the oxide semiconductor layer 140 and the gate electrode 160. The gate insulating layer 150 is in contact with the oxide semiconductor layer 140. In the main surface of the oxide semiconductor layer 140, a surface in contact with the gate insulating layer 150 is referred to as an upper surface 141. A surface between the upper surface 141 and the lower surface 142 is referred to as a side surface 143. The insulating layers 170 and 180 are arranged above the gate insulating layer 150 and the gate electrode 160. Openings 171 and 173 that reach the oxide semiconductor layer 140 are arranged in the insulating layers 170 and 180. The source electrode 201 is arranged inside the opening 171. The source electrode 201 is in contact with the oxide semiconductor layer 140 at the bottom of the opening 171. The drain electrode 203 is arranged inside the opening 173. The drain electrode 203 is in contact with the oxide semiconductor layer 140 at the bottom of the opening 173.

The gate electrode 105 has a function as a bottom-gate of the semiconductor device 10 and a function as a light-shielding film for the oxide semiconductor layer 140. The gate insulating layer 110 has a function as a barrier film for shielding impurities that diffuse from the substrate 100 toward the oxide semiconductor layer 140. The gate insulating layers 110 and 120 have a function as a gate insulating layer for the bottom-gate. The metal oxide layer 130 is a layer containing a metal oxide containing aluminum as the main component, and has a function as a gas barrier film for shielding a gas such as oxygen or hydrogen.

The oxide semiconductor layer 140 is divided into a source region S, a drain region D, and a channel region CH. The channel region CH is a region of the oxide semiconductor layer 140 vertically below the gate electrode 160. The source region S is a region of the oxide semiconductor layer 140 that does not overlap the gate electrode 160 and is closer to the source electrode 201 than the channel region CH. The drain region D is a region of the oxide semiconductor layer 140 that does not overlap the gate electrode 160 and is closer to the drain electrode 203 than the channel region CH. The oxide semiconductor layer 140 in the channel region CH has physical properties as a semiconductor. The oxide semiconductor layer 140 in the source region S and the drain region D has physical properties as a conductor.

The gate electrode 160 has a function as a top-gate of the semiconductor device 10 and a light-shielding film for the oxide semiconductor layer 140. The gate insulating layer 150 has a function as a gate insulating layer for the top-gate, and has a function of releasing oxygen by a heat treatment in a manufacturing process. The insulating layers 170 and 180 insulate the gate electrode 160 and the source-drain electrode 200 and have a function of reducing parasitic capacitance therebetween. Operations of the semiconductor device 10 are controlled mainly by a voltage supplied to the gate electrode 160. An auxiliary voltage is supplied to the gate electrode 105. However, in the case of using the gate electrode 105 simply as a light-shielding film, a specific voltage is not supplied to the gate electrode 105, and the gate electrode 105 may be in a floating state. That is, the gate electrode 105 may simply be referred to as a “light-shielding film.”

In the present embodiment, although a configuration using a dual-gate transistor in which the gate electrode is arranged both above and below the oxide semiconductor layer as the semiconductor device 10 is exemplified, the configuration is not limited to this configuration. For example, a bottom-gate transistor in which the gate electrode is arranged only below the oxide semiconductor layer or a top-gate transistor in which the gate electrode is arranged only above the oxide semiconductor layer may be used as the semiconductor device 10. The above configuration is merely an embodiment, and the present invention is not limited to the above configuration.

As shown in FIG. 2, in a plan view, a planar pattern of the metal oxide layer 130 is substantially the same as a planar pattern of the oxide semiconductor layer 140. Referring to FIG. 1 and FIG. 2, the lower surface 142 of the oxide semiconductor layer 140 is covered with the metal oxide layer 130. In particular, in the present embodiment, all of the lower surface 142 of the oxide semiconductor layer 140 is covered with the metal oxide layer 130. In a first direction D1, a width of the gate electrode 105 is greater than a width of the gate electrode 160. The first direction DI is a direction connecting the source electrode 201 and the drain electrode 203, and is a direction indicating a channel length L of the semiconductor device 10. Specifically, a length in the first direction D1 in the region (the channel region CH) where the oxide semiconductor layer 140 and the gate electrode 160 overlap is the channel length L, and a width in a second direction D2 in the channel region CH is a channel width W.

In the present embodiment, although a configuration in which all of the lower surface 142 of the oxide semiconductor layer 140 is covered with the metal oxide layer 130 is exemplified, the present invention is not limited to this configuration. For example, a part of the lower surface 142 of the oxide semiconductor layer 140 may not be in contact with the metal oxide layer 130. For example, all of the lower surface 142 of the oxide semiconductor layer 140 in the channel region CH may be covered with the metal oxide layer 130, and all or part of the lower surface 142 of the oxide semiconductor layer 140 in the source region S and the drain region D may not be covered with the metal oxide layer 130. That is, all or part of the lower surface 142 of the oxide semiconductor layer 140 in the source region S and the drain region D may not be in contact with the metal oxide layer 130. However, in the above configuration, a part of the lower surface 142 of the oxide semiconductor layer 140 in the channel region CH may not be covered with the metal oxide layer 130, and the other part of the lower surface 142 may be in contact with the metal oxide layer 130.

In the present embodiment, although a configuration in which the gate insulating layer 150 is formed on the entire surface and the openings 171 and 173 are arranged in the gate insulating layer 150 is exemplified, the configuration is not limited to this configuration. The gate insulating layer 150 may be patterned. For example, the gate insulating layer 150 may be patterned to expose the oxide semiconductor layer 140 in the source region S and the drain region D. That is, the gate insulating layer 150 in the source region S and the drain region D may be removed, and the oxide semiconductor layer 140 and the insulating layer 170 may be in contact with each other in these regions.

In FIG. 2, although a configuration in which the source-drain electrode 200 does not overlap the gate electrode 105 and the gate electrode 160 in a plan view is exemplified, the configuration is not limited to this configuration. For example, in a plan view, the source-drain electrode 200 may overlap at least one of the gate electrode 105 and the gate electrode 160. The above configuration is merely an embodiment, and the present invention is not limited to the above configuration.

### Material of Each Member of Semiconductor Device 10

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a substrate without translucency such as a semiconductor substrate such as a silicon substrate, a silicon carbide substrate, a compound semiconductor substrate, or a conductive substrate such as a stainless substrate is used as the substrate 100.

Common metal materials are used for the gate electrode 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used as these members. The above-described materials may be used in a single layer or in a stacked layer as the gate electrode 105, the gate electrode 160, and the source-drain electrode 200.

Common insulating materials are used for the gate insulating layers 110 and 120 and the insulating layers 170 and 180. For example, insulating layers such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) are used as the inorganic insulating layers.

Among the above-described insulating layers, the insulating layer containing oxygen is used as the gate insulating layer 150. For example, an inorganic insulating layer such as silicon oxide (SiOₓ), silicon oxynitride (SiOₓN_{y}), aluminum oxide (AlOₓ), and aluminum oxynitride (AlOₓN_{y}) is used as the gate insulating layer 150.

An insulating layer having a function of releasing oxygen by a heat treatment is used as the gate insulating layer 120. For example, the temperature of the heat treatment at which the gate insulating layer 120 releases oxygen is 600° C. or less, 500° C. or less, 450° C. or less, or 400° C. or less. That is, for example, in the case where the glass substrate is used as the substrate 100, the gate insulating layer 120 releases oxygen at the heat treatment temperature performed in the manufacturing process of the semiconductor device 10.

An insulating layer with few defects is used as the gate insulating layer 150. For example, when a composition ratio of oxygen in the gate insulating layer 150 is compared with a composition ratio of oxygen in an insulating layer (hereinafter referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used as the gate insulating layer 150 is close to the stoichiometric ratio of silicon oxide as compared with the composition ratio of oxygen in the silicon oxide used as the insulating layer 180. For example, a layer in which no defects are observed when evaluated by electron-spin resonance (ESR) may be used as the gate insulating layer 150.

SiOₓN_{y} and AlOₓN_{y} described above are a silicon compound and an aluminum compound containing nitrogen (N) in a ratio (x>y) smaller than that of oxygen (O). SiNₓO_{y} and AlNₓO_{y} are a silicon compound and an aluminum compound containing oxygen in a ratio (x>y) smaller than that of nitrogen.

A metal oxide containing aluminum as the main component is used as the metal oxide layer 130. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 130. The “metal oxide layer containing aluminum as the main component” means that the ratio of aluminum contained in the metal oxide layer 130 is 1% or more of the total amount of the metal oxide layer 130. The ratio of aluminum contained in the metal oxide layer 130 may be 5% or more and 70% or less, 10% or more and 60% or less, or 30% or more and 50% or less of the total amount of the metal oxide layer 130. The above ratio may be a mass ratio or a weight ratio.

A metal oxide having semiconductor properties is used as the oxide semiconductor layer 140. For example, an oxide semiconductor containing two or more metals containing indium (In) is used as the oxide semiconductor layer 140. The ratio of indium to the entire oxide semiconductor layer 140 is 50% or more. Gallium (Ga), zinc (Zn), aluminum (Al), hafnium (Hf), yttrium (Y), zirconia (Zr), and lanthanoids are used as the oxide semiconductor layer 140 in addition to indium. Elements other than those described above may be used for the oxide semiconductor layer 140.

The oxide semiconductor layer 140 may be amorphous or crystalline. The oxide semiconductor layer 140 may be a mixed phase of amorphous and crystalline. Oxygen deficiencies are likely to be formed in the oxide semiconductor layer 140 in which the ratio of indium is 50% or more, as described below. Oxygen deficiencies are less likely to be formed in a crystalline oxide semiconductor as compared with an amorphous oxide semiconductor. Therefore, the oxide semiconductor layer 140 as described above is preferably crystalline.

### Problems Newly Recognized

In the case where the ratio of indium in the oxide semiconductor layer 140 is 50% or more, the semiconductor device 10 with high mobility is realized. On the other hand, since the oxygen contained in the oxide semiconductor layer 140 is easily reduced in such an oxide semiconductor layer 140, oxygen deficiencies are easily formed in the oxide semiconductor layer 140.

In the semiconductor device 10, hydrogen is released from a layer (for example, the gate insulating layers 110 and 120) arranged closer to the substrate 100 side than the oxide semiconductor layer 140 in the heat treatment step of the manufacturing process. When the hydrogen reaches the oxide semiconductor layer 140, oxygen deficiencies occur in the oxide semiconductor layer 140. The occurrence of the oxygen deficiencies is more pronounced the larger the pattern size of the oxide semiconductor layer 140 becomes. In order to suppress the occurrence of such oxygen deficiencies, it is necessary to suppress hydrogen from reaching the lower surface 142 of the oxide semiconductor layer 140. This is the first problem.

Apart from the above problem, there is a second problem shown below. The upper surface 141 of the oxide semiconductor layer 140 is affected by a process (for example, a patterning process or an etch process) after the oxide semiconductor layer 140 is formed. On the other hand, the lower surface 142 of the oxide semiconductor layer 140 (the surface of the oxide semiconductor layer 140 facing the substrate 100) is not affected as described above.

Therefore, there are more oxygen deficiencies formed near the upper surface 141 of the oxide semiconductor layer 140 than the oxygen deficiencies formed near the lower surface 142 of the oxide semiconductor layer 140. That is, the oxygen deficiencies in the oxide semiconductor layer 140 do not exist uniformly in a thickness direction of the oxide semiconductor layer 140, but exist in a non-uniform distribution in the thickness direction of the oxide semiconductor layer 140. Specifically, there are fewer oxygen deficiencies in the oxide semiconductor layer 140 toward the lower surface 142 side of the oxide semiconductor layer 140 and more oxygen deficiencies toward the upper surface 141 side of the oxide semiconductor layer 140.

In the case where an oxygen supply process is uniformly performed on the oxide semiconductor layer 140 having the oxygen deficiency distribution as described above, oxygen is excessively supplied to the lower surface 142 side of the oxide semiconductor layer 140 when supplying oxygen in an amount required to repair the oxygen deficiencies formed on the upper surface 141 side of the oxide semiconductor layer 140. As a result, a defect level different from the oxygen deficiency is formed on the lower surface 142 side due to the excess oxygen. As a result, phenomenon such as variation in characteristics in the reliability test or a decrease in field-effect mobility occurs. Therefore, in order to suppress such phenomenon, it is necessary to supply oxygen to the upper surface 141 side of the oxide semiconductor layer 140 while suppressing the oxygen supply to the lower surface 142 side of the oxide semiconductor layer 140.

The above problems are newly recognized in the process of reaching the present invention but are not problems that have been conventionally recognized. In the conventional configuration and manufacturing method, there was a trade-off relationship between the initial characteristics and the reliability test, in which the variation in characteristics according to the reliability test occurs even when the initial characteristics of the semiconductor device are improved by the oxygen supply process to the oxide semiconductor layer. However, with the configuration according to the present embodiment, the above problems are solved, and it is possible to obtain good initial characteristics and a reliability test result of the semiconductor device 10.

Furthermore, a flatness of a surface on which the oxide semiconductor layer 140 is deposited affects the crystallinity of the oxide semiconductor layer 140. In this embodiment, the metal oxide layer 130 on which the oxide semiconductor layer 140 is deposited is usually deposited by sputtering. A surface roughness (arithmetic mean roughness Ra) immediately after the metal oxide layer 130 is deposited by sputtering is about 1 nm to 4 nm. When a surface of the metal oxide layer 130 is uneven even by 1 nm to 4 nm, crystal growth in a thickness direction of the oxide semiconductor layer 140 is inhibited when crystallization is performed by a heat treatment on the oxide semiconductor layer 140 deposited thereon. In other words, the direction of crystal growth of the oxide semiconductor layer 140 becomes random due to surface irregularities. In a semiconductor device using such an oxide semiconductor layer, further improvement in field-effect mobility cannot be expected. Therefore, there is room for improvement in order to increase the field-effect mobility of semiconductor devices.

In the semiconductor device 10 of an embodiment of the present invention, a relationship between the arithmetic mean roughness Ra (nm) of the metal oxide layer 130 and the field effect mobility μ (cm²/Vs) is expressed by the following formula.

$$μ = - 10.033 Ra + 48.23$$

(where the arithmetic mean roughness is Ra≤0.80 nm.)

In an embodiment of the invention, a top surface of the metal oxide layer 130 has flatness at an interface between the metal oxide layer 130 and the oxide semiconductor layer 140. As described below, the oxide semiconductor layer 140 is deposited over a surface with reduced surface irregularities. When the oxide semiconductor layer 140 deposited on the metal oxide layer 130 is heat treated, a direction and speed at which the crystals of the oxide semiconductor layer 140 grow can be aligned. By using the oxide semiconductor layer 140 having such crystallinity, the field-effect mobility of the semiconductor device 10 can be further improved. Specifically, the field-effect mobility of the semiconductor device 10 can be increased to 40 cm²/Vs or higher.

### Method for Manufacturing Semiconductor Device 10

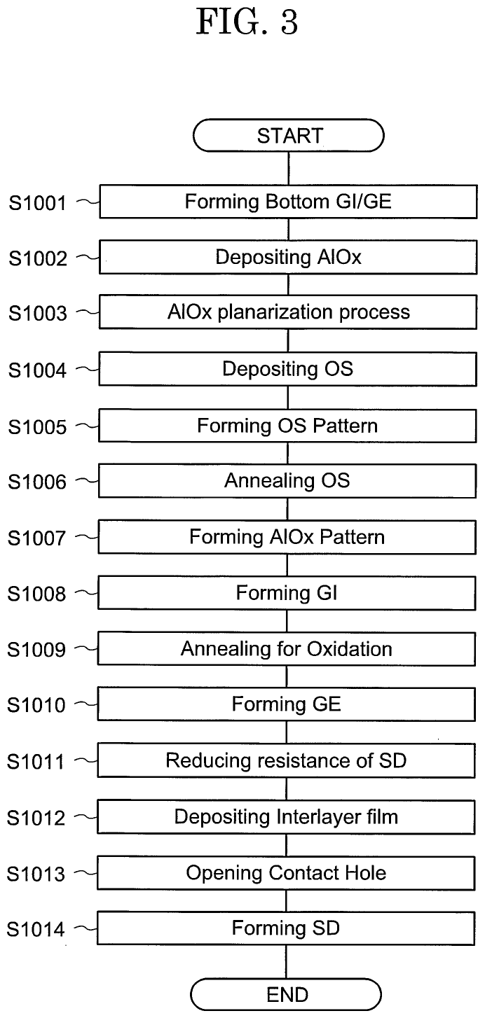

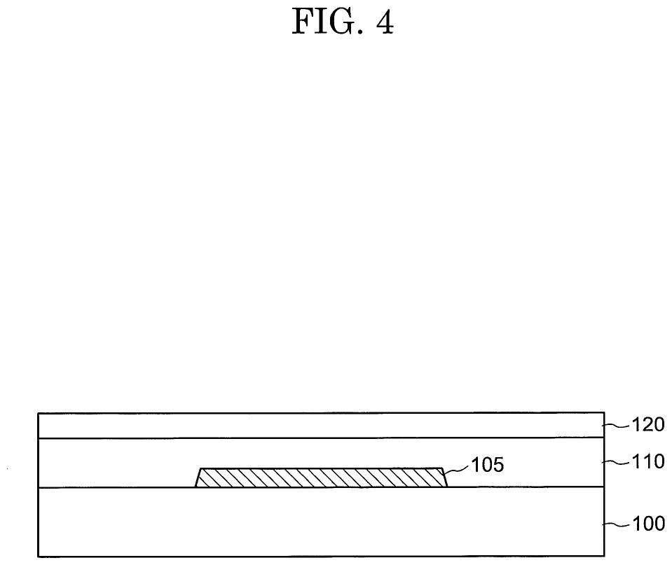

A method for manufacturing a semiconductor device according to an embodiment of the present invention will be described with reference to FIG. 3 to FIG. 13. FIG. 3 is a sequence diagram showing a method for manufacturing a semiconductor device according to an embodiment of the present invention. FIG. 4 to FIG. 13 are cross-sectional views showing a method for manufacturing a semiconductor device according to an embodiment of the present invention. In the description of the manufacturing method shown below, a method for manufacturing the semiconductor device 10 in which aluminum oxide is used as the metal oxide layers 130 will be described.

As shown in FIG. 3 and FIG. 4, the gate electrode 105 is formed on the substrate 100 as the bottom-gate, and the gate insulating layers 110 and 120 are formed on the gate electrode 105 (“Forming Bottom GI/GE” in step S1001 of FIG. 3). For example, silicon nitride is formed as the gate insulating layer 110. For example, silicon oxide is formed as the gate insulating layer 120. The gate insulating layers 110 and 120 are formed by a CVD (Chemical Vapor Deposition) method. One or both of the gate insulating layers 110 and 120 may be referred to as a “first insulating layer.”

Using silicon nitride as the gate insulating layer 110 allows the gate insulating layer 110 to block impurities that diffuse, for example, from the substrate 100 toward the oxide semiconductor layer 140. The silicon oxide used as the gate insulating layer 120 is silicon oxide having a physical property of releasing oxygen by a heat treatment.

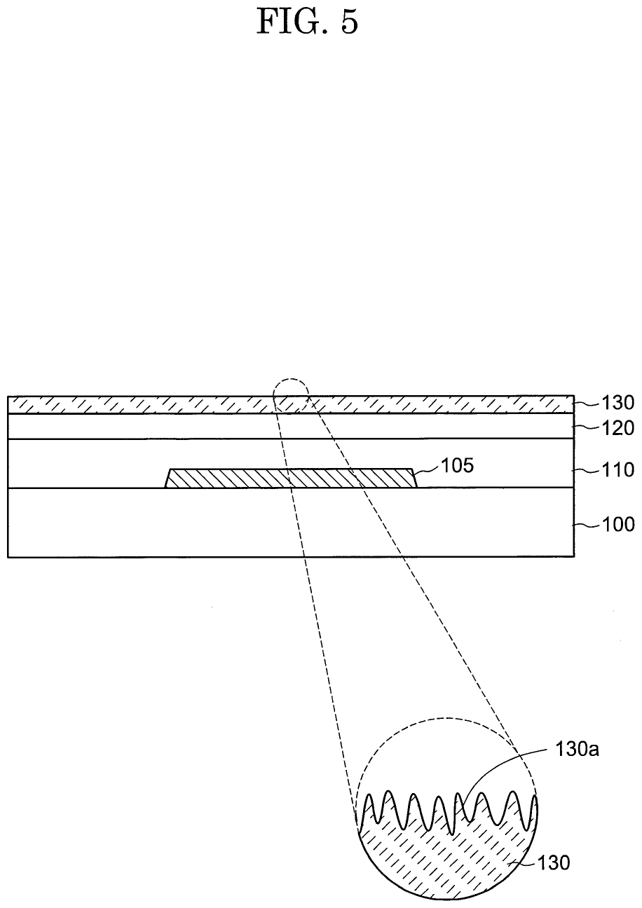

As shown in FIG. 3 and FIG. 5, the metal oxide layer 130 is formed on the gate insulating layer 120 (“Depositing AlOₓ” in step S1002 of FIG. 3). The metal oxide layer 130 is deposited by a sputtering or an atomic layer deposition method (ALD).

For example, a thickness of the metal oxide layer 130 at deposition is 6 nm or more and 60 nm or less, 6 nm or more and 50 nm or less, 6 nm or more and 25 nm or less, or 6 nm or more and 15 nm or less. The thickness of the metal oxide layer 130 may be set appropriately according to the planarization process described later. In the present embodiment, aluminum oxide is used as the metal oxide layer 130. Aluminum oxide has a high barrier property against gases such as oxygen or hydrogen. The metal oxide layer 130 is deposited by sputtering. In the present embodiment, the aluminum oxide used as the metal oxide layer 130 blocks hydrogen and oxygen released from the gate insulating layer 120, and suppresses the released hydrogen and oxygen from reaching the oxide semiconductor layer 140.

A surface of the metal oxide layer 130 immediately after deposition has surface irregularities of 1 nm to 4 nm. When crystallizing the oxide semiconductor layer 140, which is deposited on the metal oxide layer 130, if the surface irregularities of even 1 nm to 4 nm exist, a direction of crystal growth will be random. However, it is difficult to sputter the metal oxide layer 130 so that the surface irregularity is less than 1 nm. Therefore, it is preferable to make the surface irregularity of the metal oxide layer 130 less than 1 nm by performing a planarization process on the surface of the metal oxide layer 130.

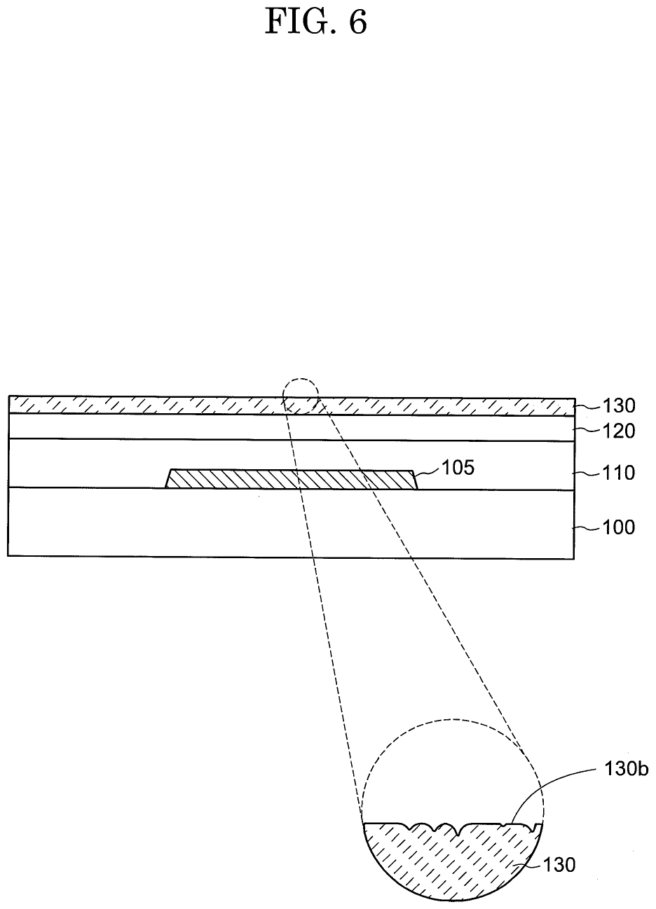

As shown in FIG. 3 and FIG. 6, the planarization process is performed on the oxidized metal layer 130 (“AlOx planarization process” in step S1003 of FIG. 3). Wet etching process or a plasma process is used as the planarization process for AlOx.

When the planarization process is performed by wet etching, an alkaline chemical solution is used as a chemical solution, for example, a developer solution to remove resist materials. Solutions of tetramethylammonium hydroxide (TMAH) or potassium hydroxide (KOH) solutions are used as alkaline chemicals. Acidic chemical solutions such as phosphoric acid, nitric acid, hydrofluoric acid, hydrochloric acid, sulfuric acid, acetic acid, oxalic acid, or a mixture of these solutions may also be used. For example, a mixed acid containing phosphoric acid, nitric acid, and acetic acid may be used as an acidic chemical solution. It is preferable to remove 5 nm or more of the surface of the metal oxide layer 130 by wet etching, and it is more preferable to remove 40 nm or more. When the thickness of the metal oxide layer 130 is 6 nm or more and 25 nm or less, or 6 nm or more and 15 nm or less at the time of deposition, the thickness of the metal oxide layer 130 is 1 nm or more and 20 nm or less, preferably 1 nm or more and 10 nm or less by the planarization process. The arithmetic mean roughness of the metal oxide layer 130, as measured by observing the surface of the metal oxide layer 130 with AFM at 1000 nm square and 10 nm height (fixed), should be Ra<1 nm, Ra≤0.80, and Ra≤0.73 nm is more preferred. When wet etching is used as the planarization process, it can also serve as a cleaning process before depositing the oxide semiconductor layer 140.

When the planarization process is performed by a plasma process, it is performed by reverse sputtering or etching. When the plasma process is performed by reverse sputtering, an inert gas such as argon gas, helium gas, or nitrogen gas may be used. When the plasma process is performed by reverse sputtering, oxygen gas may be used, or a mixture of oxygen gas and an inert gas may be used. Alternatively, when the plasma process is performed in etching, halogen gas such as chlorine gas or fluorine gas may be used. It is preferable to remove 5 nm or more of the surface of the metal oxide layer 130 by the plasma process. When the thickness of the metal oxide layer 130 is 6 nm or more and 60 nm or less, or 6 nm or more and 50 nm or less at the time of deposition, the thickness of the metal oxide layer 130 is 1 nm or more and 20 nm or less, preferably 1 nm or more and 10 nm or less by the planarization process. The arithmetic mean roughness of the metal oxide layer 130, as measured by observing the surface of the metal oxide layer 130 with an AFM at 1000 nm square and 10 nm height (fixed), should be Ra<1 nm, Ra≤0.73 nm, and Ra≤0.67 is more preferred. When the plasma process is performed as the planarization process, particles adhering to the surface can also be removed.

A method for evaluating a flatness of the surface of the metal oxide layer 130 will be described. The flatness of the metal oxide layer 130 can be evaluated using an atomic force microscope (AFM: Atomic Force Microscope). A roughness curve is obtained by AFM analysis. Based on a roughness curve, an arithmetic mean roughness (Ra), a root mean square roughness (Rq), a maximum height difference (Rmax), and the like are obtained as roughness curve parameters.

The arithmetic mean roughness (Ra) is an average of absolute values of the ordinate Z(X) at the reference length. The lower the arithmetic mean roughness (Ra), the higher the flatness of the film. An ordinate value Z(X) is a height of the roughness curve at any position X. A root mean square height (Rq) is the root mean square at a reference length. It represents a standard deviation of a surface roughness.

The above roughness curve parameters are defined according to JIS B 0601-2001 (equivalent to ISO 4287-1997).

The roughness curve parameter of the metal oxide layer 130 may be calculated using a contrast of a cross-sectional TEM image of the semiconductor device instead of an atomic force microscope. In the cross-sectional TEM image, a contrast (brightness) of the metal oxide layer 130 and the oxide semiconductor layer 140 are different. Therefore, the boundary of the contrast between the metal oxide layer 130 and the oxide semiconductor layer 140 may be approximated as a roughness curve on the surface of the metal oxide layer 130. Based on the approximated roughness curve, the arithmetic mean roughness (Ra) and a root mean square roughness (Rq) may be calculated as roughness curve parameters according to JIS B 0601-2001.

A thickness of the metal oxide layer after the planarization process is 1 nm or more and 20 nm or less, preferably 1 nm or more and 10 nm or less.

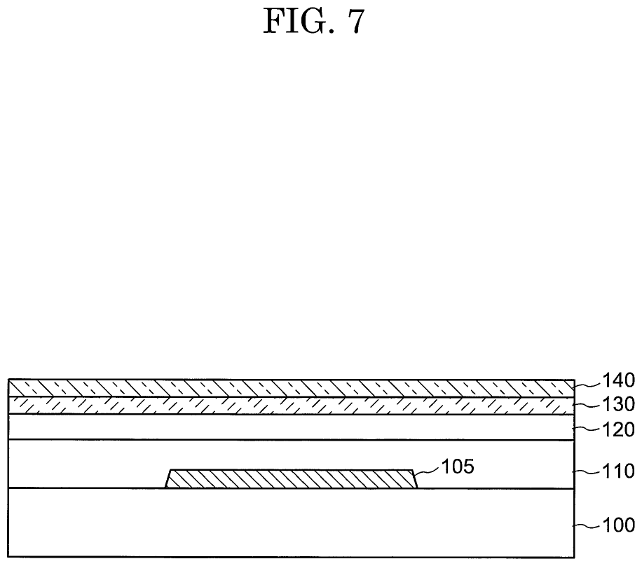

As shown in FIG. 3 and FIG. 7, the oxide semiconductor layer 140 is deposited on the planarized metal oxide layer 130 (“OS deposition” in step S1004 of FIG. 3).

For example, a thickness of the oxide semiconductor layer 140 is 10 nm or more and 100 nm or less, 15 nm or more and 70 nm or less, or 20 nm or more and 40 nm or less. In this embodiment, an oxide containing indium (In) and gallium (Ga) is used as the oxide semiconductor layer 140. Before the heat treatment (OS anneal) described below, the oxide semiconductor layer 140 is amorphous. The oxide semiconductor layer 140 before the heat treatment (OS anneal) described later is amorphous.

When the oxide semiconductor layer 140 is crystallized by the OS anneal process described later, the oxide semiconductor layer 140 after the deposition and before the OS anneal is preferably in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals occur in the oxide semiconductor layer 140 immediately after the deposition process. The microcrystals inhibit crystallization by a subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or less, 70° C. or less, 50° C. or less, or 30° C. or less. As described above, depositing the oxide semiconductor layer 140 while cooling the object to be deposited makes it possible to deposit the oxide semiconductor layer 140 with few crystalline components in a state immediately after the deposition.

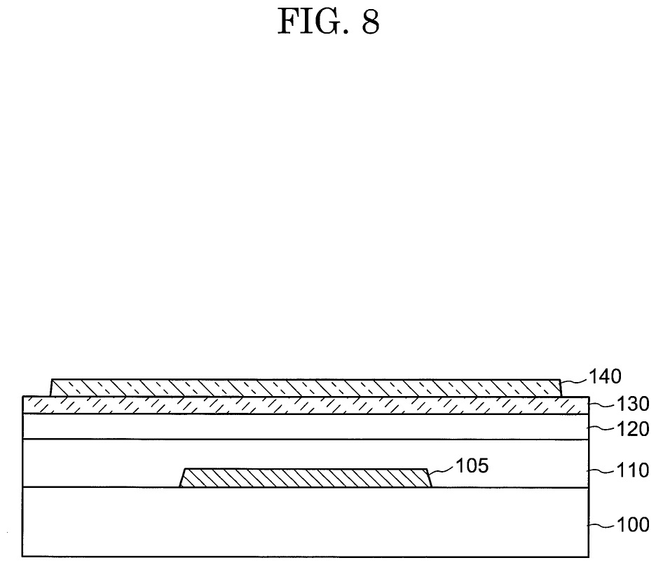

As shown in FIG. 3 and FIG. 8, a pattern of the oxide semiconductor layer 140 is formed (“Forming OS Pattern” in step S1005 of FIG. 3). Although not shown, a resist mask is formed on the oxide semiconductor layer 140, and the oxide semiconductor layer 140 is etched using the resist mask. Wet etching may be used, or dry etching may be used as the etching method of the oxide semiconductor layer 140. The wet etching may include etching using an acidic etchant. For example, oxalic acid or hydrofluoric acid may be used as the etchant.

A heat treatment (OS anneal) (“Annealing OS” in step S1006 of FIG. 3) is performed on the oxide semiconductor layer 140 after the pattern of the oxide semiconductor layer 140 is formed. In the present embodiment, the oxide semiconductor layer 140 is crystallized by the OS anneal. In this embodiment, the arithmetic mean roughness Ra of the metal oxide layer 130 is reduced to less than 1 nm, preferably 0.80 nm or less, more preferably 0.73 nm or less. The oxide semiconductor layer 140 is formed on a flat surface where surface irregularities of the metal oxide layer 130 are suppressed. Therefore, when the oxide semiconductor layer 140 is crystallized by OS annealing, the direction of crystal growth is suppressed to be random, and the direction and speed of crystal growth can be aligned. As a result, the oxide semiconductor layer 140 can be formed with crystallinity in which the directions of crystal growth are aligned.

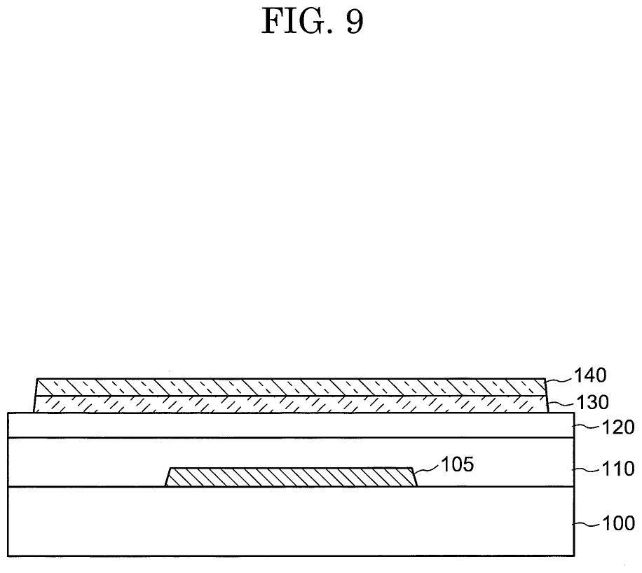

As shown in FIG. 3 and FIG. 9, a pattern of the metal oxide layer 130 is formed (“Forming AlOₓ Pattern” in step S1007 of FIG. 3). The metal oxide layer 130 is etched using the oxide semiconductor layer 140 patterned in the above process as a mask. Wet etching may be used, or dry etching may be used as the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

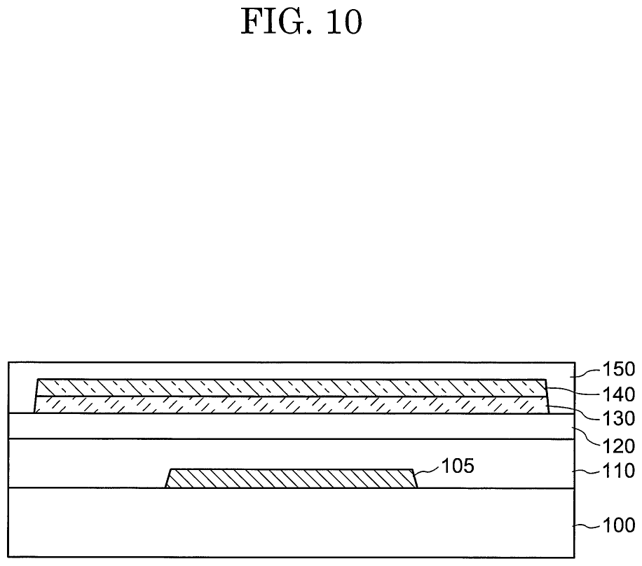

As shown in FIG. 3 and FIG. 10, the gate insulating layer 150 is deposited on the oxide semiconductor layer 140 (“Forming GI” in step S1008 of FIG. 3). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer having few defects as described above. For example, the thickness of the gate insulating layer 150 is 50 nm or more and 300 nm or less, 60 nm or more and 200 nm or less, or 70 nm or more and 150 nm or less. An oxygen implantation process may be performed on a portion of the gate insulating layer 150 after the gate insulating layer 150 is deposited.

A heat treatment (oxidation anneal) for supplying oxygen to the oxide semiconductor layer 140 is performed in a state where the gate insulating layer 150 is deposited on the oxide semiconductor layer 140 and the metal oxide layer 190 is deposited on the gate insulating layer 150 (“Annealing for Oxidation” in step S1009 of FIG. 3). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the annealing for oxidation described above, and the oxygen deficiency are repaired.

Oxygen released from the gate insulating layer 120 by the oxidation anneal is blocked by the metal oxide layer 130. Therefore, oxygen is less likely to be supplied to the lower surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 via the gate insulating layer 150. As a result, the oxygen released from the gate insulating layer 120 is less likely to be supplied to the lower surface 142 of the oxide semiconductor layer 140, and is mainly supplied to the side surface 143 and the upper surface 141 of the oxide semiconductor layer 140. Further, the oxidation anneal makes it possible to supply oxygen released from the gate insulating layer 150 to the upper surface 141 and the side surface 143 of the oxide semiconductor layer 140. The oxidation anneal may release hydrogen from the gate insulating layers 110 and 120 but the hydrogen is blocked by the metal oxide layer 130.

As described above, in the annealing for oxidation step, it is possible to supply oxygen to the upper surface 141 and the side surface 143 of the oxide semiconductor layer 140 having a large amount of oxygen deficiencies while suppressing the supply of oxygen to the lower surface 142 of the oxide semiconductor layer 140 having a small amount of oxygen deficiencies.

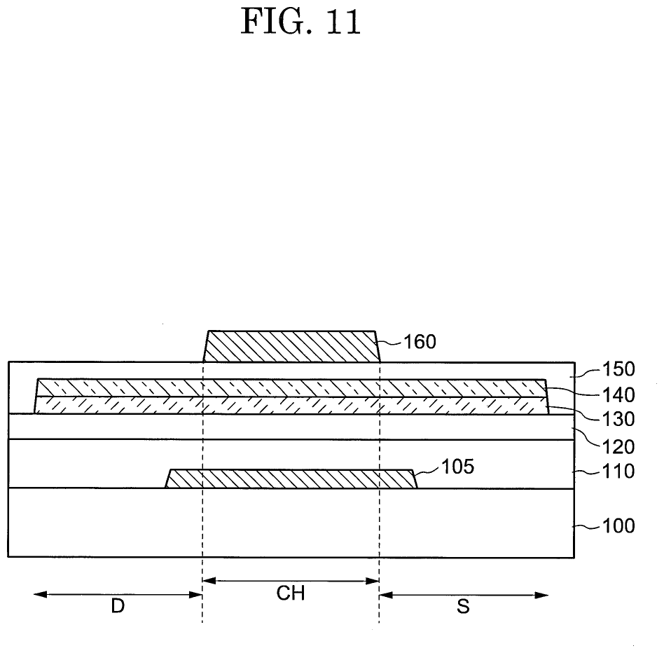

As shown in FIG. 3 and FIG. 11, the gate electrode 160 is deposited on the gate insulating layer 150 (“Forming GE” in step S1010 of FIG. 3). The gate electrode 160 is deposited by the sputtering method or the atomic layer deposition method and patterned through the photolithography process.

Resistances of the source region S and the drain region D of the oxide semiconductor layer 140 are reduced (“Reducing resistance of SD” in step S1011 of FIG. 3) in a state where the gate electrode 160 is patterned. Specifically, impurities are implanted into the oxide semiconductor layer 140 from the gate electrode 160 side via the gate insulating layer 150 by ion implantation. For example, argon (Ar), phosphorus (P), and boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 functioning as the channel region CH of the semiconductor device 10, impurities are not implanted into the oxide semiconductor layer 140 in the channel region CH.

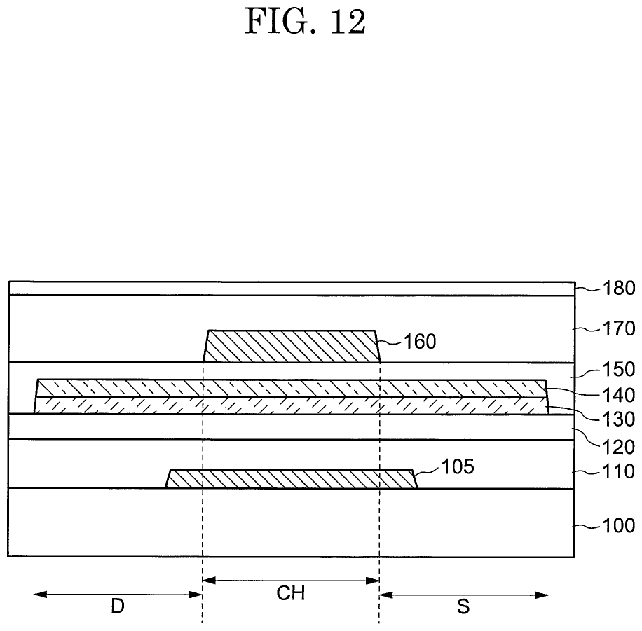

As shown in FIG. 3 and FIG. 12, the insulating layers 170 and 180 are deposited on the gate insulating layer 150 and the gate electrode 160 as interlayer films (“Depositing Interlayer film” in step S1012 of FIG. 3). The insulating layers 170 and 180 are deposited by the CVD method. For example, silicon nitride is formed as the insulating layer 170, and silicon oxide is formed as the insulating layer 180. The materials used as the insulating layers 170 and 180 are not limited to the above. A thickness of the insulating layer 170 is 50 nm or more and 500 nm or less. A thickness of the insulating layer 180 is 50 nm or more and 500 nm or less.

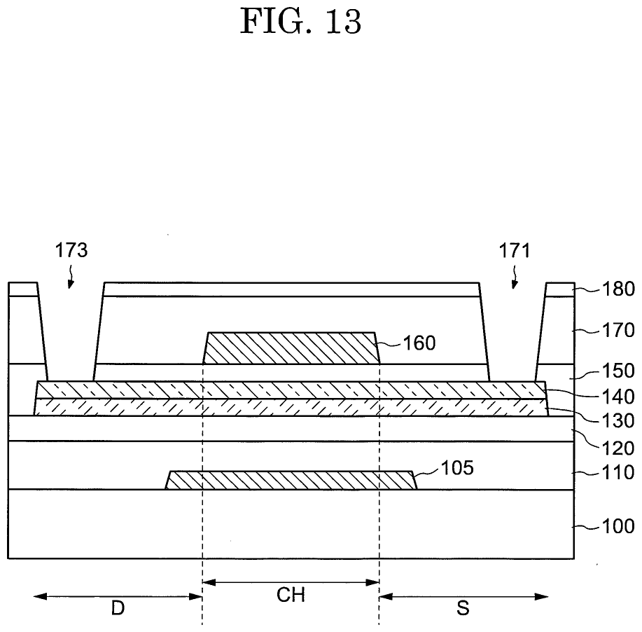

As shown in FIG. 3 and FIG. 13, the openings 171 and 173 are formed in the gate insulating layer 150 and the insulating layers 170 and 180 (“Opening Contact Hole” in step S1013 of FIG. 3). The oxide semiconductor layer 140 in the source region S is exposed by the opening 171. The oxide semiconductor layer 140 in the drain region D is exposed by the opening 173. The semiconductor device 10 shown in FIG. 1 is completed by forming the source-drain electrode 200 on the oxide semiconductor layer 140 exposed by the openings 171 and 173 and on the insulating layer 180 (“Forming SD” in step S1014 of FIG. 3).

With respect to the semiconductor device 10 manufactured by the above-described manufacturing method, in the oxide semiconductor layer 140, the direction and speed of crystal growth can be aligned. As a result, it is possible to obtain electrical characteristics having a mobility of 30 [cm²/Vs] or more, 35 [cm²/Vs] or more, or 40 [cm²/Vs] or more in a range where the channel length L of the channel region CH in the semiconductor device 10 is 2 μm or more and 4 μm or less and the channel width of the channel region CH is 2 μm or more and 25 μm or less. The mobility in the present embodiment is the field-effect mobility in a saturation region in the electrical characteristics of the semiconductor device 10. Specifically, the mobility means the largest value of the field-effect mobility in a region where a potential difference (Vd) between the source electrode and the drain electrode is greater than a value (Vg−Vth) obtained by subtracting a threshold-voltage (Vth) of the semiconductor device 10 from a voltage (Vg) supplied to the gate electrode.

In the semiconductor device 10 in which the metal oxide layer 130 is planarized by wet etching in the above manufacturing method, a relationship between an arithmetic mean roughness Ra (nm) of a surface of the metal oxide layer 130 and the field effect mobility μ (cm²/Vs) is expressed by the following formula.

$$μ = - 10.033 Ra + 48.23$$

(Where the arithmetic mean roughness Ra≤0.80)

In the semiconductor device 10 in which the metal oxide layer 130 is planarized by a plasma process in the above manufacturing method, a relationship between an arithmetic mean roughness Ra (nm) of a surface of the metal oxide layer 130 and the electric field effect mobility μ (cm²/Vs) is expressed by the following formula.

$$μ = - 5.9584 Ra + 43.978$$

(Where the arithmetic mean roughness Ra≤0.67)

In the semiconductor device 10 in which the metal oxide layer 130 is planarized by wet etching or a plasma process in the above manufacturing method, the relationship between the arithmetic mean roughness Ra (nm) of the surface of the metal oxide layer 130 and the field effect mobility μ (cm²/Vs) is expressed by the following formula.

$$μ = - 5.77 Ra + 44.22$$

(Where the arithmetic mean roughness Ra≤0.73)

### Modification 1 of First Embodiment

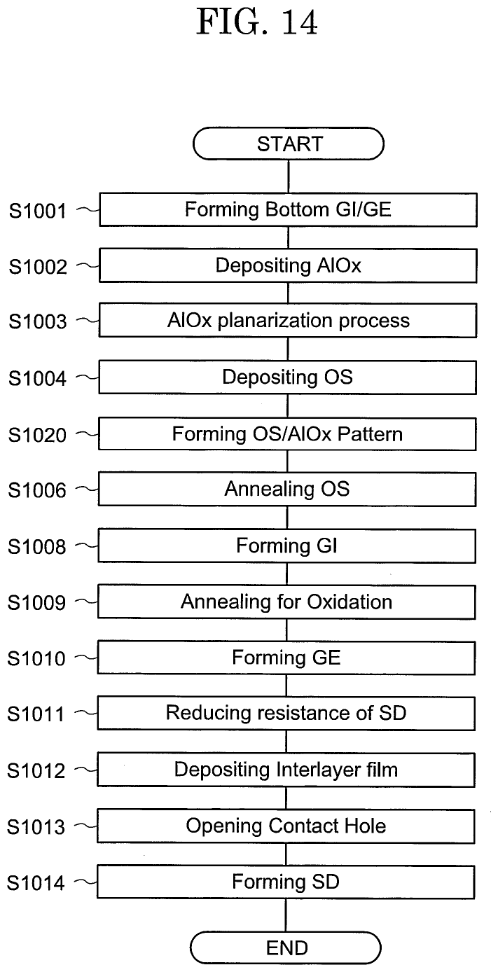

Modification 1 of the present embodiment will be described with reference to FIG. 14 to FIG. 16. Although a structure of the semiconductor device 10 according to Modification 1 is the same as that of FIG. 1, the method for manufacturing thereof is different from that of FIG. 3 to FIG. 13. In the following description, the description of the manufacturing method common to the manufacturing method shown in FIG. 3 to FIG. 13 is omitted, and the manufacturing method relating to the difference between the two manufacturing methods will be mainly described.

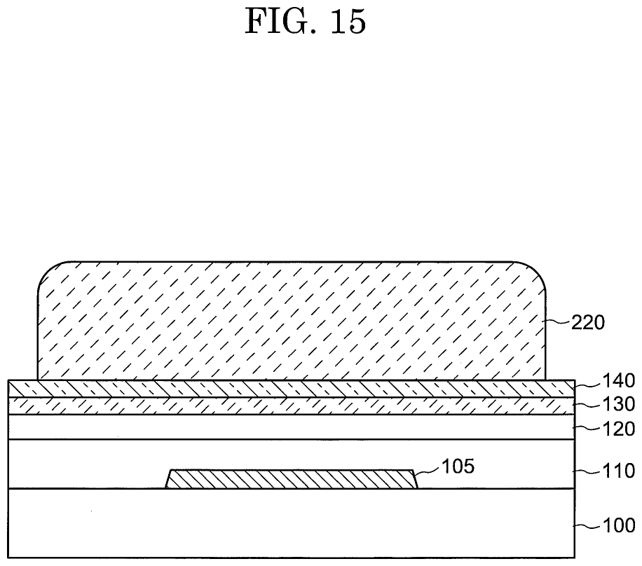

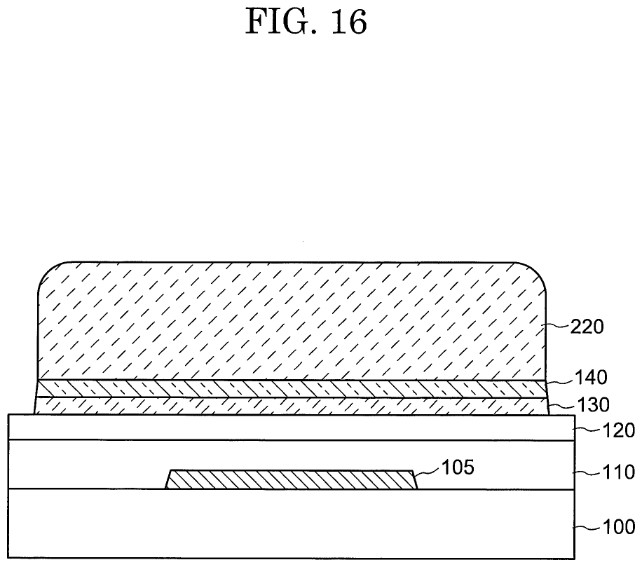

FIG. 14 is a sequence diagram showing a method for manufacturing a semiconductor device according to a modification of an embodiment of the present invention. FIG. 15 and FIG. 16 are cross-sectional views showing a manufacturing process of a semiconductor device according to a modification of an embodiment of the present invention. As shown in FIG. 14, in Modification 1, patterns of the metal oxide layer 130 and the oxide semiconductor layer 140 are collectively formed (“Forming OS/AlOₓ pattern” in step S1020).

As shown in FIG. 15, a resist mask 220 is formed on the oxide semiconductor layer 140 after the metal oxide layer 130 and the oxide semiconductor layer 140 are deposited. Then, as shown in FIG. 16, the patterns of the metal oxide layer 130 and the oxide semiconductor layer 140 are formed using the resist mask 220. Wet etching may be used, or dry etching may be used as the etching method of the metal oxide layer 130 and the oxide semiconductor layer 140. In the case where the metal oxide layer 130 and the oxide semiconductor layer 140 are etched by wet etching, an etchant similar to that described above can be used. In Modification 1, the OS anneal is performed in a state where the patterns of the metal oxide layer 130 and the oxide semiconductor layer 140 are formed (step S1006). Since the subsequent steps S1008 to S1014 are the same as those in FIG. 3, detailed descriptions thereof will be omitted.

### Modification 2 of First Embodiment

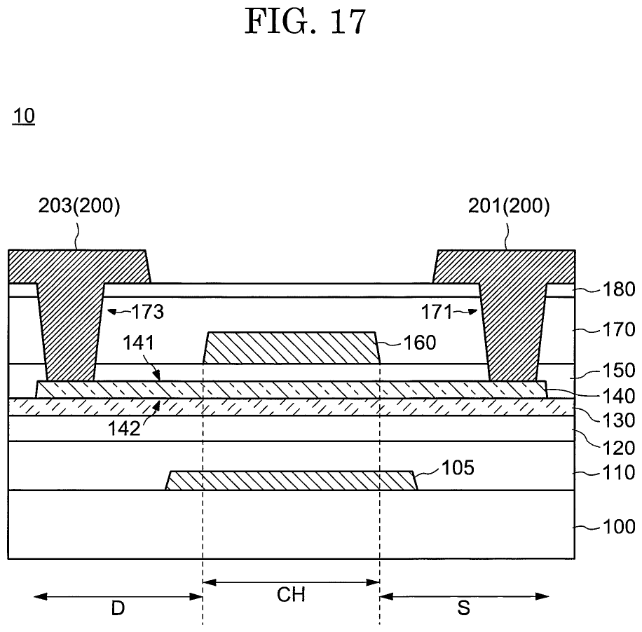

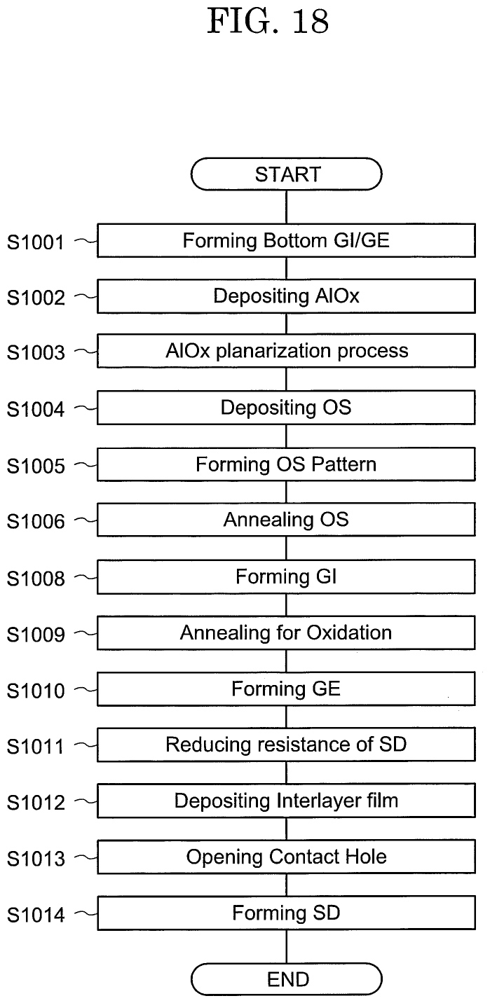

Modification 2 of the present embodiment will be described with reference to FIG. 17 and FIG. 18. A structure and a method for manufacturing the semiconductor device 10 according to Modification 2 are different from those of FIG. 1 and FIG. 3 to FIG. 13. In the following description, the description of the manufacturing method common to the manufacturing method shown in FIG. 1 and FIG. 3 to FIG. 13 is omitted, and the manufacturing method relating to the difference between the two manufacturing methods will be mainly described.

FIG. 17 is a cross-sectional view showing an outline of a semiconductor device according to a modification of an embodiment of the present invention. FIG. 18 is a sequence diagram showing a method for manufacturing a semiconductor device according to a modification of the embodiment.

As shown in FIG. 17, a structure of the semiconductor device 10 according to Modification 2 is similar to the structure of the semiconductor device 10 shown in FIG. 1 but Modification 2 is different from the structure of the semiconductor device 10 shown in FIG. 1 in that the pattern of the metal oxide layer 130 is not formed. That is, in Modification 2, the metal oxide layer 130 extends outward from the pattern of the oxide semiconductor layer 140. The metal oxide layer 130 is in contact with the gate insulating layer 150 outside the patterned oxide semiconductor layer 140.

As shown in FIG. 18, the method for manufacturing the semiconductor device 10 according to Modification 2 is similar to the method for manufacturing the semiconductor device 10 shown in FIG. 3 but Modification 2 is different from the method for manufacturing the semiconductor device 10 shown in FIG. 3 in that the patterning formation process of the metal oxide layer 130 (step S1007 in FIG. 3) is omitted. Since the subsequent steps S1008 to S1014 are the same as those in FIG. 3, detailed descriptions thereof will be omitted.

### Modification 3 of First Embodiment

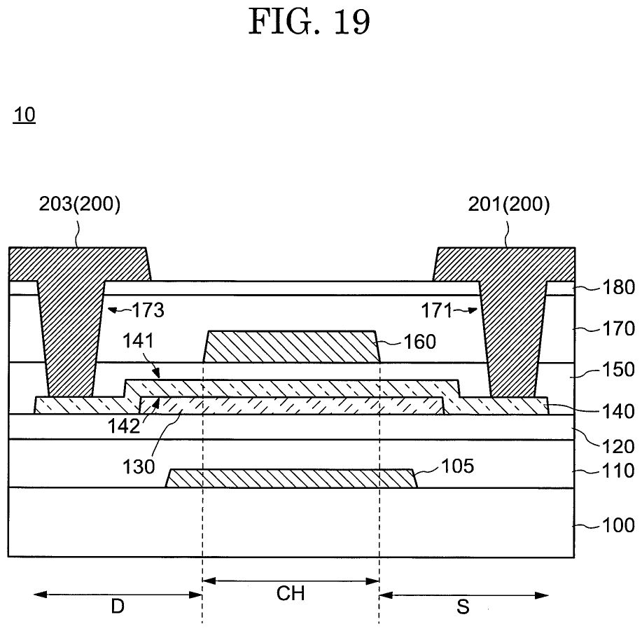

Modification 3 of the present embodiment will be described with reference to FIG. 19 to FIG. 23. A structure and a method for manufacturing the semiconductor device 10 according to Modification 3 are different from those of FIG. 1 to FIG. 13. In the following description, the description of the manufacturing method common to the manufacturing method shown in FIG. 1 to FIG. 13 will be omitted, and the manufacturing method relating to the difference between the two manufacturing methods will be mainly described.

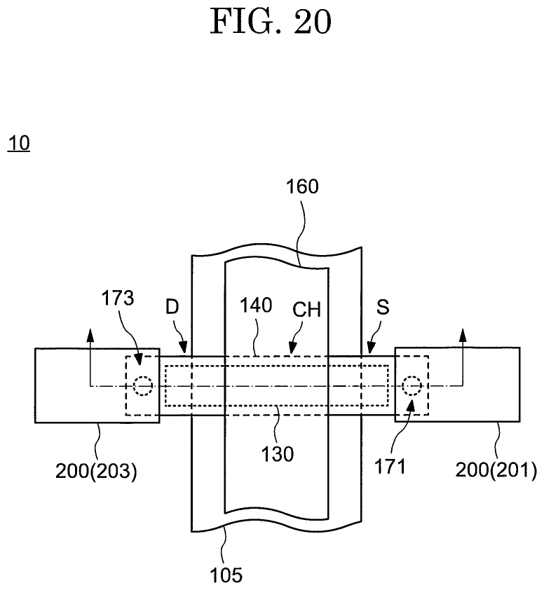

FIG. 19 is a cross-sectional view showing an outline of a semiconductor device according to an embodiment of the present invention. FIG. 20 is a plan view showing an outline of a semiconductor device according to an embodiment of the present invention.

As shown in FIG. 19 and FIG. 20, the structure of the semiconductor device 10 according to Modification 3 is similar to the structure of the semiconductor device 10 shown in FIG. 1 and FIG. 2 but Modification 3 is different from the structure of the semiconductor device 10 shown in FIG. 1 in that the pattern of the metal oxide layer 130 is different from the pattern of the oxide semiconductor layer 140. Specifically, in the cross-sectional view of FIG. 19, the pattern of the oxide semiconductor layer 140 extends outward from the pattern of the metal oxide layer 130. That is, the oxide semiconductor layer 140 crosses over the pattern of the metal oxide layer 130. The oxide semiconductor layer 140 is in contact with the gate insulating layer 120 outside the pattern of the metal oxide layer 130. The gate insulating layer 120 may be referred to as a “first insulating layer.”

The source-drain electrode 200 is in contact with the oxide semiconductor layer 140 in a region where the metal oxide layer 130 is not provided. In the plan view of FIG. 20, a pattern of the metal oxide layer 130 is located inside a pattern of the oxide semiconductor layer 140. The openings 171 and 173 are provided in a region that does not overlap the pattern of the metal oxide layer 130.

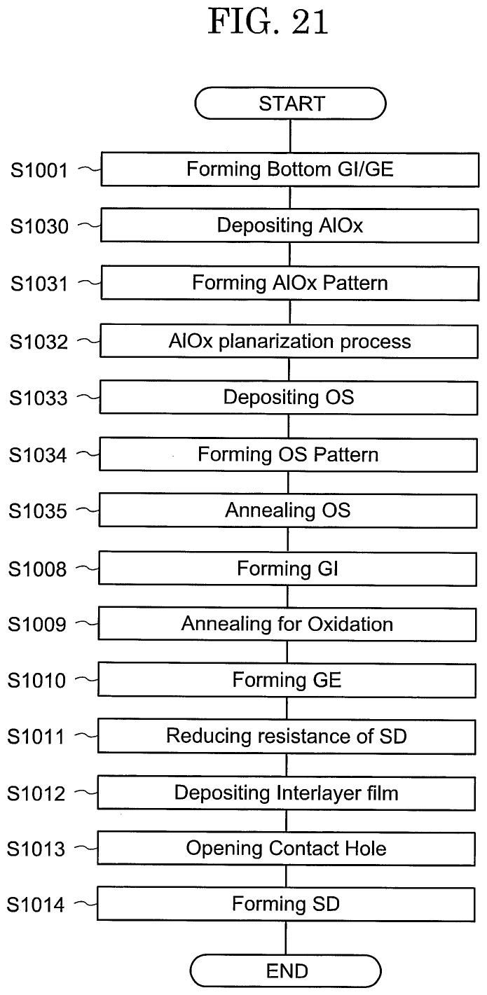

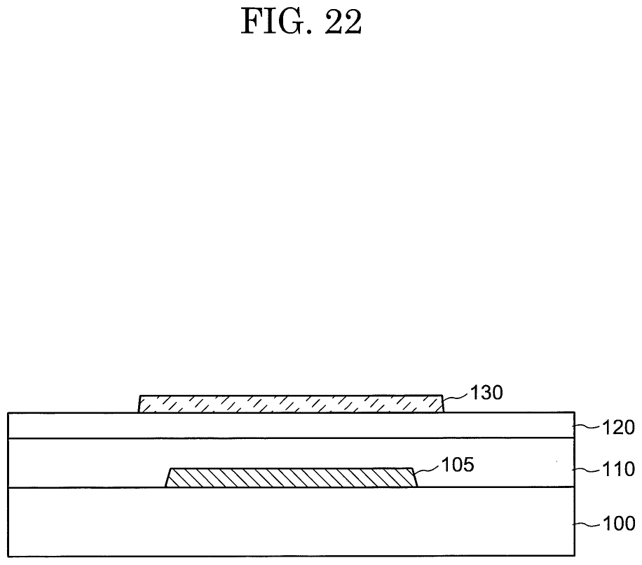

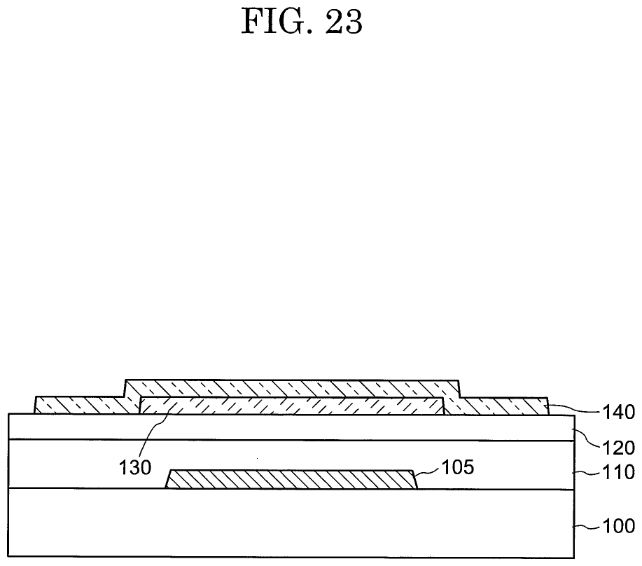

FIG. 21 is a sequence diagram showing a method for manufacturing a semiconductor device according to an embodiment of the present invention. FIG. 22 and FIG. 23 are cross-sectional views showing a method for manufacturing a semiconductor device according to an embodiment of the present invention. As shown in FIG. 21, in Modification 3, after forming the pattern of the metal oxide layer 130 (“AlOₓ deposition” in step S1030 and “AlOₓ pattern formation” in step S1031), a planarization process is performed on the metal oxide layer 130 (step S1032). After that, the oxide semiconductor layer 140 is patterned (“OS deposition” in step S1033 and “OS pattern formation” in step S1034). Unlike in FIG. 3, OS annealing (“OS annealing” in step S1035) is performed after the gate insulating layer 150 is formed.

As shown in FIG. 22, the metal oxide layer 130 is deposited on the gate insulating layer 120 (step S1030), and a pattern of the metal oxide layer 130 is formed (step S1031). The patterning (etching) of the metal oxide layer 130 is performed in the same manner as above. Thereafter, the planarization process is performed on the surface of the patterned metal oxide layer 130 (step S1032).

As shown in FIG. 23, the oxide semiconductor layer 140 is deposited on the patterned metal oxide layer 130 (step S1033), and a pattern of the oxide semiconductor layer 140 is formed (step S1034). The patterning (etching) of the oxide semiconductor layer 140 is performed in the same manner as above. Then, OS annealing is performed in the state shown in FIG. 23 (step S1035). Subsequent steps S1008 to S1014 are the same as in FIG. 3, so a detailed description is omitted.

As described above, according to the semiconductor device 10 according to Modifications 1 to 3 of the present embodiment, the same effects as in the present embodiment can be obtained.

### Second Embodiment

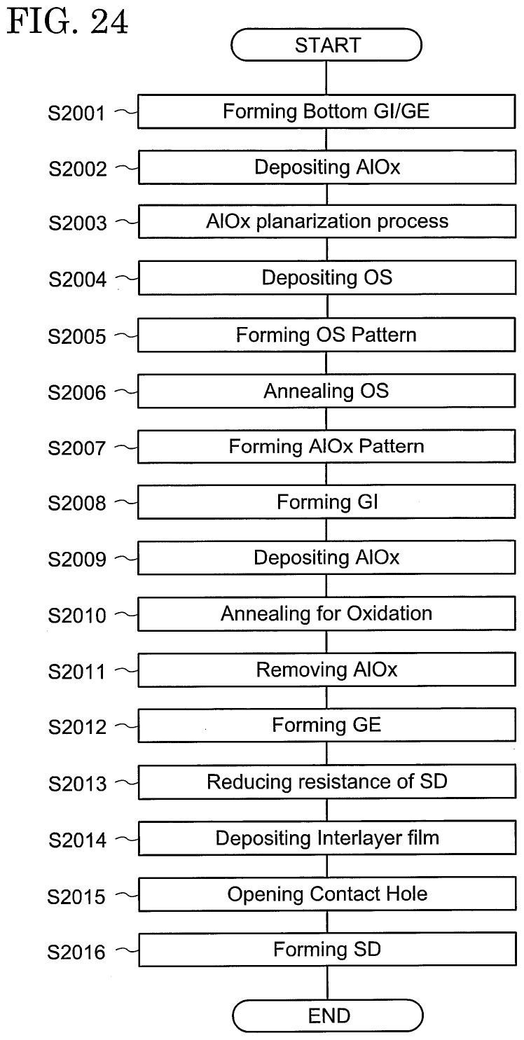

FIG. 24 to FIG. 35 are used to describe a semiconductor device according to an embodiment of the present invention.

### Configuration of Semiconductor Device 10

The configuration of the semiconductor device 10 for this embodiment is the same as that of the first embodiment. Therefore, the semiconductor device 10 according to this embodiment will be described with reference to FIG. 1 and FIG. 2. The semiconductor device 10 according to this embodiment differs from the semiconductor device 10 according to the first embodiment in the manufacturing method. Therefore, in this embodiment, the description of the configuration of the semiconductor device 10 is omitted and its manufacturing method is described. In the following description, the same material as the metal oxide layer 130 is used as the metal oxide layer 190.

### Method for Manufacturing Semiconductor Device 10

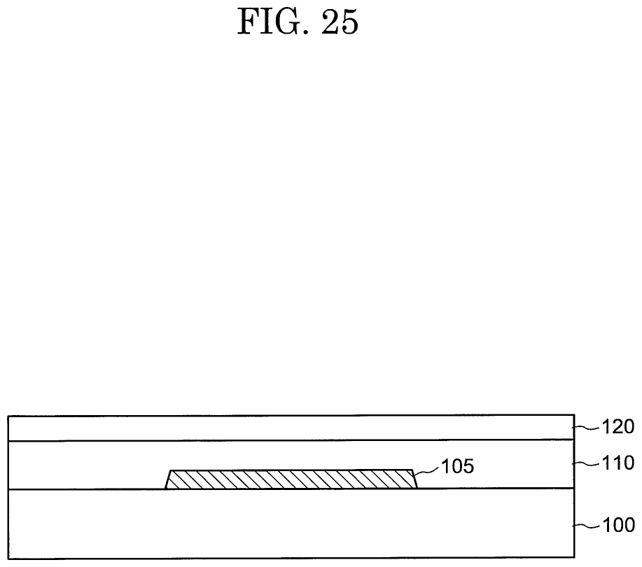

FIG. 24 to FIG. 35 are used to describe a method for manufacturing the semiconductor device according to an embodiment of the present invention. FIG. 24 is a sequence diagram showing a method for manufacturing a semiconductor device according to an embodiment of the present invention. FIG. 25 to FIG. 35 are cross-sectional diagrams showing the method for manufacturing a semiconductor device according to an embodiment of the present invention. In the following description of the manufacturing method, the method for manufacturing the semiconductor device 10 in which aluminum oxide is used as the metal oxide layers 130 and 190 will be described.

As shown in FIG. 24 and FIG. 25, the gate electrode 105 is formed on the substrate 100 as the bottom-gate, and the gate insulating layers 110 and 120 are formed on the gate electrode 105 (“Bottom GI/GE formation” in step S2001 of FIG. 24). For example, silicon nitride is formed as the gate insulating layer 110. For example, silicon oxide is formed as the gate insulating layer 120. The gate insulating layers 110 and 120 are formed by a CVD (Chemical Vapor Deposition) method.

Using silicon nitride as the gate insulating layer 110 allows the gate insulating layer 110 to block impurities diffusing, for example, from the substrate 100 toward the oxide semiconductor layer 140. The silicon oxide used as the gate insulating layer 120 is silicon oxide having a physical property of releasing oxygen by a heat treatment.

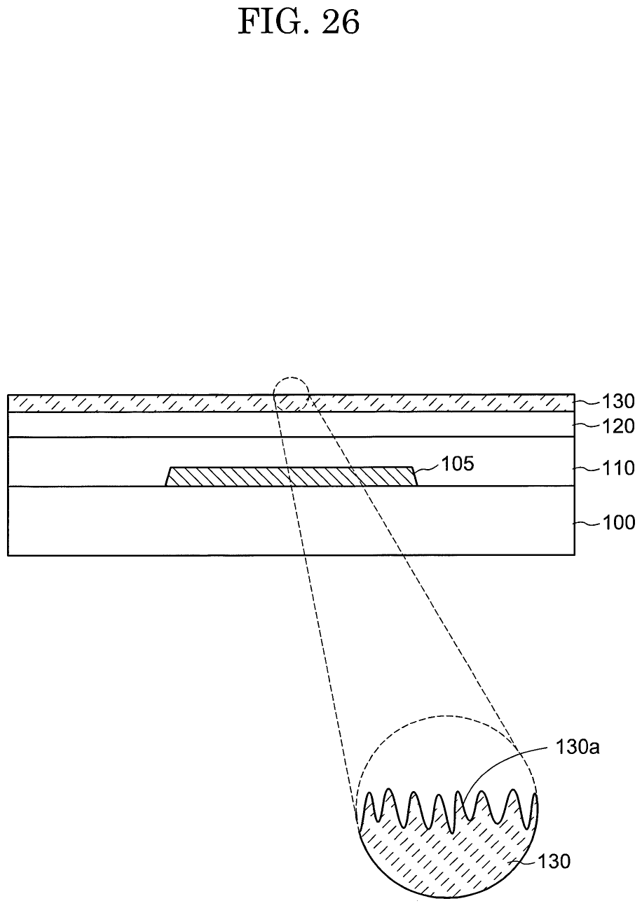

As shown in FIG. 24 and FIG. 26, the metal oxide layer 130 and an oxide semiconductor layer 140 are formed on the gate insulating layer 120 (“AlOₓ deposition” in step S2002 of FIG. 24). The metal oxide layer 130 is deposited by a sputtering method or an atomic layer deposition method (ALD).

For example, the thickness of the metal oxide layer 130 at deposition is 6 nm or more and 60 nm or less, 6 nm or more and 50 nm or less, 6 nm or more and 25 nm or less, or 6 nm or more and 15 nm or less. The thickness of the metal oxide layer 130 may be set appropriately according to the planarization process described later. In the present embodiment, aluminum oxide is used as the metal oxide layer 130. Aluminum oxide has a high barrier property against gases such as oxygen and hydrogen. The metal oxide layer 130 is deposited by sputtering. In the present embodiment, the aluminum oxide used as the metal oxide layer 130 blocks hydrogen and oxygen released from the gate insulating layer 120, and suppresses the released hydrogen and oxygen from reaching the oxide semiconductor layer 140.

The surface of the metal oxide layer 130 immediately after deposition has surface irregularities of 1 nm to 4 nm. When crystallizing the oxide semiconductor layer 140, which is deposited on the metal oxide layer 130, if surface irregularities of even 1 nm to 4 nm exist, the direction of crystal growth will be random. However, it is difficult to sputter the metal oxide layer 130 so that the surface irregularities are less than 1 nm. Therefore, it is preferable to make the surface irregularities of the metal oxide layer 130 less than 1 nm by performing a planarization process on the surface of the metal oxide layer 130.

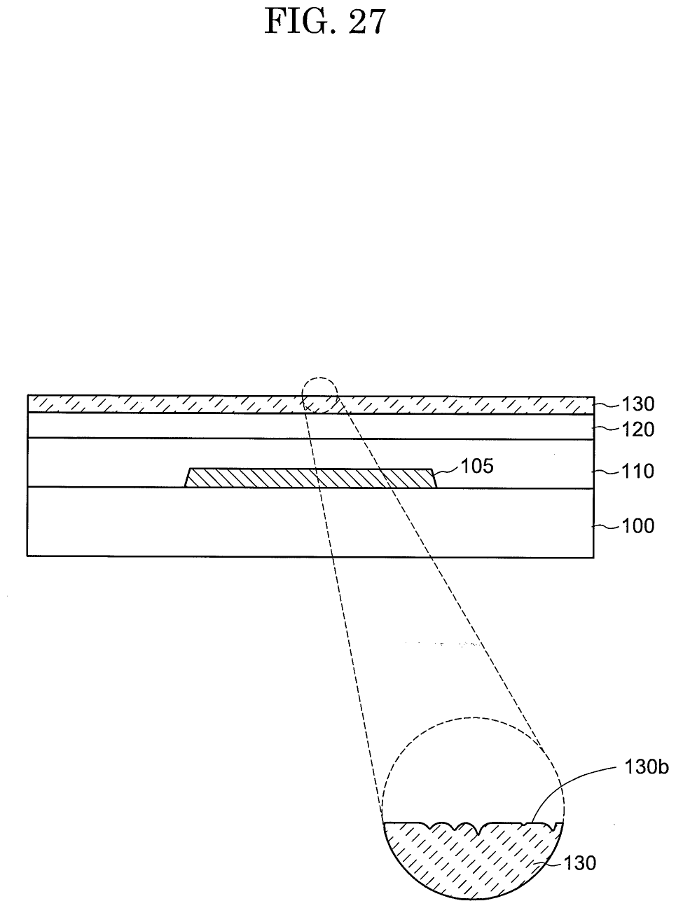

As shown in FIG. 24 and FIG. 27, the planarization process is performed on the oxidized metal layer 130 (“AlOₓ planarization process” in step S2003 of FIG. 3). A wet etching process or plasma process is used as the planarization process for AlOₓ.

When the planarization process is performed by a wet etching process, an alkaline chemical solution, such as a chemical solution, for example, a developer solution to remove resist materials is used. Solutions of tetramethylammonium hydroxide (TMAH) or potassium hydroxide (KOH) solutions are used as alkaline chemicals. Acidic chemical solutions such as phosphoric acid, nitric acid, hydrofluoric acid, hydrochloric acid, sulfuric acid, acetic acid, oxalic acid, or a mixture of these solutions may also be used. For example, a mixed acid containing phosphoric acid, nitric acid, and acetic acid may be used as an acidic chemical solution. It is preferable to remove 5 nm or more of the surface of the metal oxide layer 130 by wet etching, and it is more preferable to remove 40 nm or more. When the thickness of the metal oxide layer 130 is 6 nm or more and 25 nm or less, or 6 nm or more and 15 nm or less at the time of deposition, the thickness of the metal oxide layer 130 is 1 nm or more and 20 nm or less, preferably 1 nm or more and 10 nm or less by the planarization process. The arithmetic mean roughness of the metal oxide layer 130, as measured by observing the surface of the metal oxide layer 130 with AFM at 1000 nm square and 10 nm height (fixed), should be Ra<1 nm, Ra≤0.80, and Ra≤0.73 nm is more preferred. When wet etching is used as the planarization process, it can also serve as a cleaning process before depositing the oxide semiconductor layer 140.

When the planarization process is performed by a plasma process, it is performed by reverse sputtering or etching. When the plasma process is performed by reverse sputtering, an inert gas such as argon gas, helium gas, or nitrogen gas may be used. When the plasma process is performed by reverse sputtering, oxygen gas may be used, or a mixture of oxygen gas and an inert gas may be used. Alternatively, when the plasma process is performed in etching, halogen gas such as chlorine gas or fluorine gas may be used. It is preferable to remove 5 nm or more of the surface of the metal oxide layer 130 by the plasma process. When the thickness of the metal oxide layer 130 is 6 nm or more and 60 nm or less, or 6 nm or more and 50 nm less at the time of deposition, the thickness of the metal oxide layer 130 is 1 nm or more and 20 nm or less, preferably 1 nm or more and 10 nm or less by the planarization process. The arithmetic mean roughness of the metal oxide layer 130, as measured by observing the surface of the metal oxide layer 130 with an AFM at 1000 nm square and 10 nm height (fixed), should be Ra<1 nm, Ra≤0.73 nm, and Ra≤0.67 is more preferred. When the plasma process is performed as the planarization process, particles adhering to the surface can also be removed.

A method for evaluating a flatness of the surface of the metal oxide layer 130 will be described. A roughness curve is obtained by AFM analysis. Based on a roughness curve, an arithmetic mean roughness (Ra), a root mean square roughness (Rq), a maximum height difference (Rmax), and the like are obtained as roughness curve parameters.

A thickness of the metal oxide layer after the planarization process is 1 nm or more and 20 nm or less, preferably 1 nm or more and 10 nm or less.

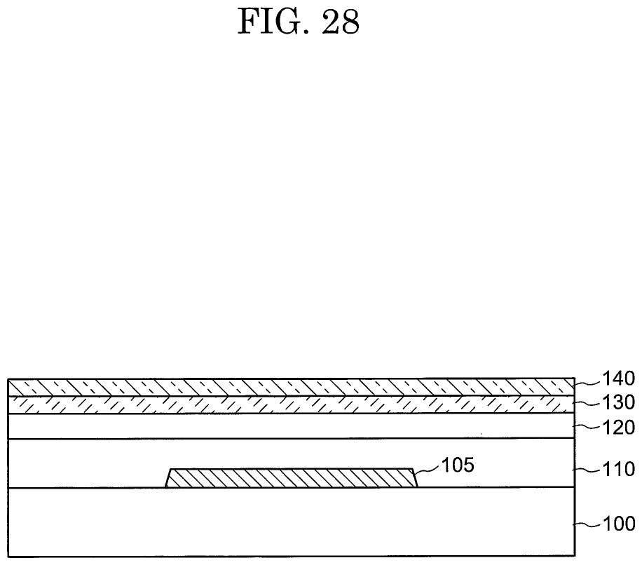

As shown in FIG. 24 and FIG. 28, the oxide semiconductor layer 140 is deposited on the planarized metal oxide layer 130 (“OS deposition” in step S2004 of FIG. 24).

For example, the thickness of the oxide semiconductor layer 140 is 10 nm or more and 100 nm or less, 15 nm or more and 70 nm or less, or 20 nm or more and 40 nm or less. In this embodiment, an oxide containing indium (In) and gallium (Ga) is used as the oxide semiconductor layer 140. Before the heat treatment (OS anneal) described below, the oxide semiconductor layer 140 is amorphous. The oxide semiconductor layer 140 before the heat treatment (OS anneal) described later is amorphous.

When the oxide semiconductor layer 140 is crystallized by the OS anneal described later, the oxide semiconductor layer 140 after the deposition and before the OS anneal is preferably in an amorphous state (a state in which there are less low crystalline components of the oxide semiconductor). That is, the deposition conditions of the oxide semiconductor layer 140 are preferred to be such that the oxide semiconductor layer 140 immediately after the deposition does not crystallize as much as possible. For example, in the case where the oxide semiconductor layer 140 is deposited by the sputtering method, the oxide semiconductor layer 140 is deposited in a state where the temperature of the object to be deposited (the substrate 100 and structures formed thereon) is controlled.

In the case where the deposition is performed on the object to be deposited by the sputtering method, ions generated in the plasma and atoms recoiled by a sputtering target collide with the object to be deposited. Therefore, the temperature of the object to be deposited rises with the deposition process. When the temperature of the object to be deposited rises during the deposition process, microcrystals occur in the oxide semiconductor layer 140 immediately after the deposition process. The microcrystals inhibit crystallization by a subsequent OS anneal. For example, in order to control the temperature of the object to be deposited as described above, deposition may be performed while cooling the object to be deposited. For example, the object to be deposited may be cooled from a surface opposite to a deposited surface so that the temperature of the deposited surface of the object to be deposited (hereinafter, referred to as “deposition temperature”) is 100° C. or less, 70° C. or less, 50° C. or less, or 30° C. or less. As described above, depositing the oxide semiconductor layer 140 while cooling the object to be deposited makes it possible to deposit the oxide semiconductor layer 140 with few crystalline components in a state immediately after the deposition.

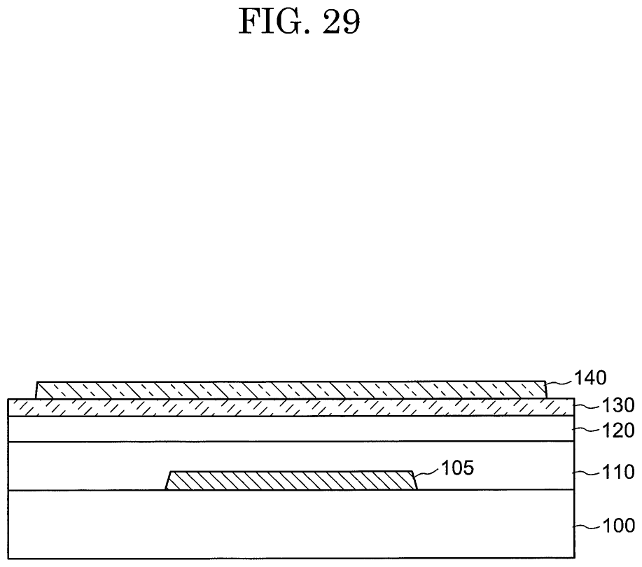

As shown in FIG. 24 and FIG. 29, a pattern of the oxide semiconductor layer 140 is formed (“Forming OS Pattern” in step S2005 of FIG. 24). Although not shown, a resist mask is formed on the oxide semiconductor layer 140, and the oxide semiconductor layer 140 is etched using the resist mask. Wet etching may be used, or dry etching may be used as the etching method of the oxide semiconductor layer 140. The wet etching may include etching using an acidic etchant. For example, oxalic acid or hydrofluoric acid may be used as the etchant.

After the patterning of the oxide semiconductor layer 140, a heat treatment (“Annealing OS” in step S2006 of FIG. 24) is performed on the oxide semiconductor layer 140. In this embodiment, the oxide semiconductor layer 140 is crystallized by this OS anneal.

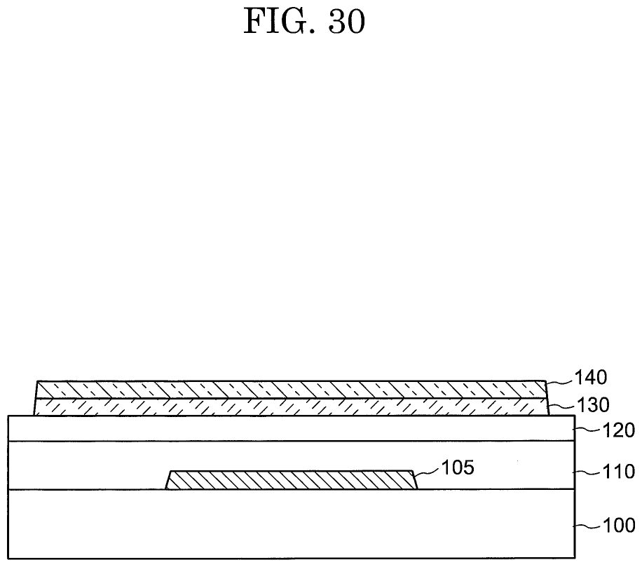

As shown in FIG. 24 and FIG. 30, a pattern of the metal oxide layer 130 is formed (“Forming AlOx Pattern” in step S2007 of FIG. 24). The metal oxide layer 130 is etched using the oxide semiconductor layer 140 patterned in the above process as a mask. Wet etching may be used, or dry etching may be used as the etching method of the metal oxide layer 130. For example, dilute hydrofluoric acid (DHF) is used for the wet etching. As described above, a photolithography process can be omitted by etching the metal oxide layer 130 using the oxide semiconductor layer 140 as the mask.

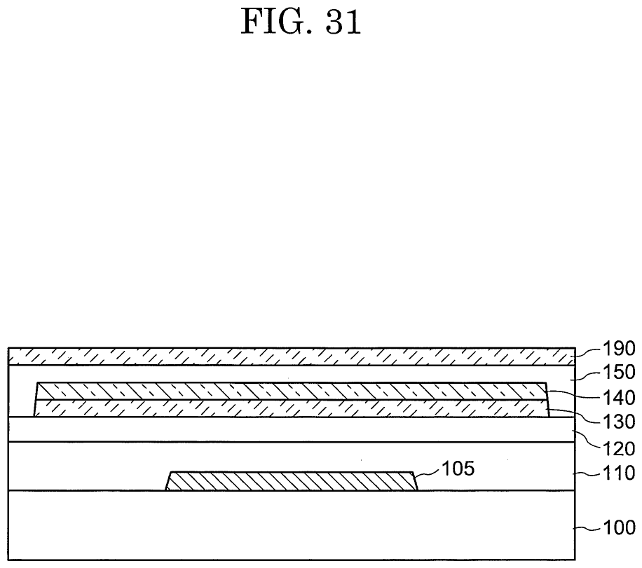

As shown in FIG. 24 and FIG. 31, the gate insulating layer 150 is deposited (“Forming GI” in step S2008 of FIG. 24). For example, silicon oxide is formed as the gate insulating layer 150. The gate insulating layer 150 is formed by the CVD method. For example, the gate insulating layer 150 may be deposited at a deposition temperature of 350° C. or higher in order to form an insulating layer having few defects as described above as the gate insulating layer 150. For example, the thickness of the gate insulating layer 150 is 50 nm or more and 300 nm or less, 60 nm or more and 200 nm or less, or 70 nm or more and 150 nm or less. An oxygen implantation process may be performed on a portion of the gate insulating layer 150 after the gate insulating layer 150 is deposited. An metal oxide layer 190 is deposited on the gate insulating layer 150 (“Depositing AlOx” in step S2009 of FIG. 24). The metal oxide layer 190 is deposited by a sputtering method. The deposition of the metal oxide layer 190 causes oxygen to be hammered into the gate insulating layer 150.

For example, a thickness of the metal oxide layer 190 is 5 nm or more and 100 nm or less, 5 nm or more and 50 nm or less, 5 nm or more and 30 nm or less, or 7 nm or more and 15 nm or less. In this embodiment, aluminum oxide is used as the metal oxide layer 190. Aluminum oxide has a high barrier property against gases such as oxygen and hydrogen. In this embodiment, the aluminum oxide used as the metal oxide layer 190 suppresses an outward diffusion of oxygen that is launched into the gate insulating layer 150 during the deposition of the metal oxide layer 190.

For example, when the metal oxide layer 190 is formed by sputtering, the process gas used in sputtering remains in the film of the metal oxide layer 190. For example, when Ar is used as the process gas for sputtering, Ar may remain in the film of the metal oxide layer 190. Residual Ar can be detected by SIMS (Secondary Ion Mass Spectrometry) analysis of the metal oxide layer 190.

With the gate insulating layer 150 deposited on the oxide semiconductor layer 140 and the metal oxide layer 190 deposited on the gate insulating layer 150, a heat treatment (Annealing for Oxidation) is performed to provide oxygen to the oxide semiconductor layer 140 (“Annealing for Oxidation” in step S2010 of FIG. 24). In the process from the deposition of the oxide semiconductor layer 140 to the deposition of the gate insulating layer 150 on the oxide semiconductor layer 140, a large amount of oxygen deficiencies occur in the upper surface 141 and the side surface 143 of the oxide semiconductor layer 140. Oxygen released from the gate insulating layers 120 and 150 is supplied to the oxide semiconductor layer 140 by the above-described oxidation anneal, and the oxygen deficiencies are repaired.

Oxygen released from the gate insulating layer 120 by the oxidation anneal is blocked by the metal oxide layer 130. Therefore, oxygen is less likely to be supplied to the lower surface 142 of the oxide semiconductor layer 140. The oxygen released from the gate insulating layer 120 diffuses from a region where the metal oxide layer 130 is not formed to the gate insulating layer 150 arranged on the gate insulating layer 120 and reaches the oxide semiconductor layer 140 via the gate insulating layer 150. As a result, the oxygen released from the gate insulating layer 120 is less likely to be supplied to the lower surface 142 of the oxide semiconductor layer 140, and is mainly supplied to the side surface 143 and the upper surface 141 of the oxide semiconductor layer 140. Further, the oxidation anneal makes it possible to supply oxygen released from the gate insulating layer 150 to the upper surface 141 and the side surface 143 of the oxide semiconductor layer 140. The oxidation anneal may release hydrogen from the gate insulating layers 110 and 120 but the hydrogen is blocked by the metal oxide layer 130.

As described above, in the oxidation anneal step, it is possible to supply oxygen to the upper surface 141 and the side surface 143 of the oxide semiconductor layer 140 having a large amount of oxygen deficiencies while suppressing the supply of oxygen to the lower surface 142 of the oxide semiconductor layer 140 having a small amount of oxygen deficiencies.

Similarly, in the above oxidation annealing, the oxygen hammered into the gate insulating layer 150 is blocked by the metal oxide layer 190. Therefore, the release of the oxygen into the atmosphere is suppressed. Therefore, the oxygen is efficiently supplied to the oxide semiconductor layer 140 by the oxidation annealing, and the oxygen deficiencies are repaired.

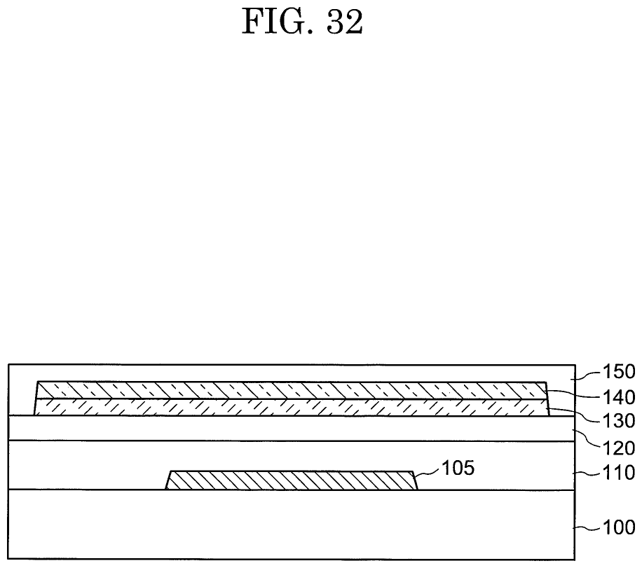

As shown in FIG. 24 and FIG. 32, after oxidation annealing, the oxide metal layer 190 is etched (removed) (“Removing AlOx” in step S2011 of FIG. 24). Wet etching or dry etching may be used as etching of the metal oxide layer 190. Diluted hydrofluoric acid (DHF) is used, for example, for the wet etching.

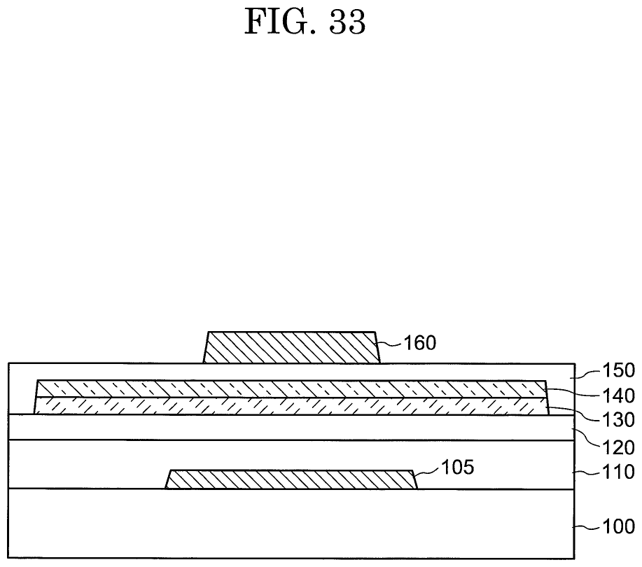

As shown in FIG. 24 and FIG. 33, the gate electrode 160 is deposited (“Forming GE” in step S2012 of FIG. 24). The gate electrode 160 is deposited by sputtering or atomic layer deposition and patterned through a photolithography process.

Resistances of the source region S and the drain region D of the oxide semiconductor layer 140 are reduced (“Reducing resistance of SD” in step S2013 of FIG. 24) in a state where the gate electrode 160 is patterned. Specifically, impurities are implanted into the oxide semiconductor layer 140 from the gate electrode 160 side via the gate insulating layer 150 by ion implantation. For example, argon (Ar), phosphorus (P), and boron (B) are implanted into the oxide semiconductor layer 140 by the ion implantation. Oxygen deficiencies are formed in the oxide semiconductor layer 140 by the ion implantation, thereby reducing the resistance of the oxide semiconductor layer 140. Since the gate electrode 160 is arranged above the oxide semiconductor layer 140 functioning as the channel region CH of the semiconductor device 10, impurities are not implanted into the oxide semiconductor layer 140 in the channel region CH.

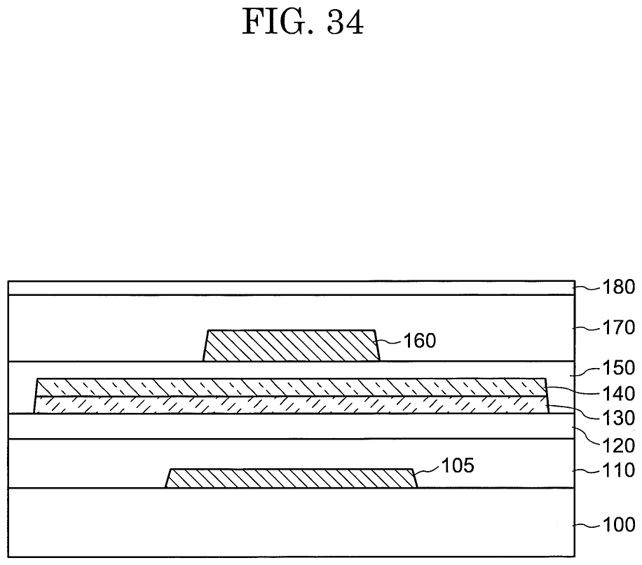

As shown in FIG. 24 and FIG. 34, the insulating layers 170 and 180 are deposited on the gate insulating layer 150 and the gate electrode 160 as interlayer films (“Depositing Interlayer film” in step S2014 of FIG. 24). The insulating layers 170 and 180 are deposited by the CVD method. For example, silicon nitride is formed as the insulating layer 170, and silicon oxide is formed as the insulating layer 180. The materials used as the insulating layers 170 and 180 are not limited to the above. The thickness of the insulating layer 170 is 50 nm or more and 500 nm or less. The thickness of the insulating layer 180 is 50 nm or more and 500 nm or less.

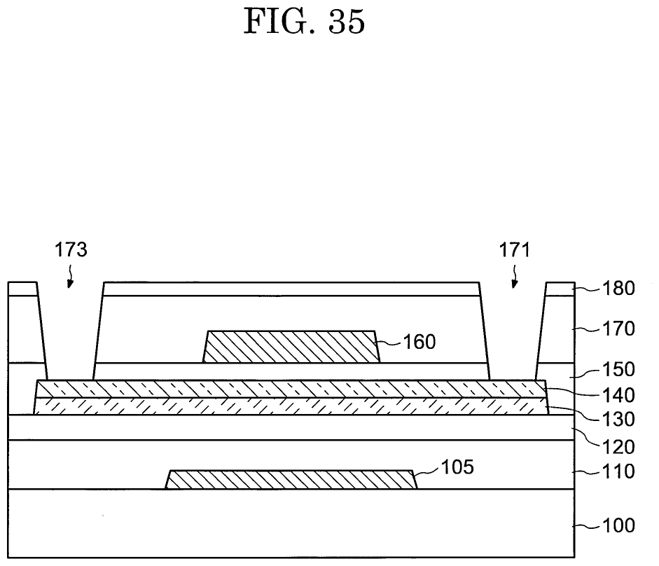

As shown in FIG. 24 and FIG. 35, the openings 171 and 173 are formed in the gate insulating layer 150 and the insulating layers 170 and 180 (“Opening Contact Hole” in step S2015 of FIG. 24). The oxide semiconductor layer 140 in the source region S is exposed by the opening 171. The oxide semiconductor layer 140 in the drain region D is exposed by the opening 173. The semiconductor device 10 shown in FIG. 1 is completed by forming the source-drain electrode 200 on the oxide semiconductor layer 140 exposed by the openings 171 and 173 and on the insulating layer 180 (“Forming SD” in step S2016 of FIG. 24).

With respect to the semiconductor device 10 manufactured by the above-described manufacturing method, in the oxide semiconductor layer 140, the direction and speed of crystal growth can be aligned. As a result, it is possible to obtain electrical characteristics having a mobility of 50 [cm²/Vs] or more, 55 [cm²/Vs] or more, or 60 [cm²/Vs] or more in a range where the channel length L of the channel region CH in the semiconductor device 10 is 2 μm or more and 4 μm or less and the channel width of the channel region CH is 2 μm or more and 25 μm or less. The mobility in the present embodiment is the field-effect mobility in a saturation region in the electrical characteristics of the semiconductor device 10. Specifically, the mobility means the largest value of the field-effect mobility in a region where a potential difference (Vd) between the source electrode and the drain electrode is greater than a value (Vg−Vth) obtained by subtracting a threshold-voltage (Vth) of the semiconductor device 10 from a voltage (Vg) supplied to the gate electrode.

In the semiconductor device 10 in which the metal oxide layer 130 is planarized by a wet etching in the above manufacturing method, the relationship between the arithmetic mean roughness Ra (nm) of the surface of the metal oxide layer 130 and the field effect mobility μ (cm²/Vs) is expressed by the following formula.

$$μ = - 10.033 Ra + 48.23$$

(Where the arithmetic mean roughness Ra≤0.80)

In the semiconductor device 10 in which the metal oxide layer 130 is planarized by a plasma process in the above manufacturing method, the relationship between the arithmetic mean roughness Ra (nm) of a surface of the metal oxide layer 130 and the electric field effect mobility μ (cm²/Vs) is expressed by the following formula.

$$μ = - 5.9584 Ra + 43.978$$

(Where the arithmetic mean roughness Ra≤0.67)

In the semiconductor device 10 in which the metal oxide layer 130 is planarized by a wet etching or a plasma process in the above manufacturing method, the relationship between the arithmetic mean roughness Ra (nm) of the surface of the metal oxide layer 130 and the field effect mobility μ (cm²/Vs) is expressed by the following formula.

$$μ = - 5.77 Ra + 44.22$$

(Where the arithmetic mean roughness Ra≤0.73)

### Third Embodiment

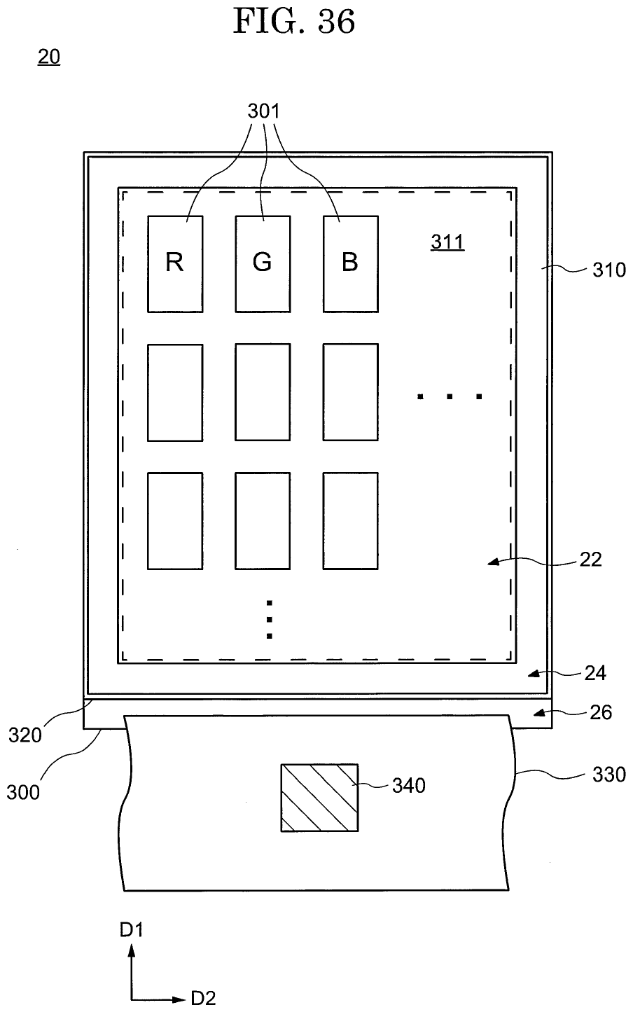

A display device using a semiconductor device according to an embodiment of the present invention will be described with reference to FIG. 36 to FIG. 40. In the embodiment shown below, a configuration in which the semiconductor device 10 described in the first embodiment and the second embodiment described above is applied to the circuit of the liquid crystal display device will be described.

### Outline of Display Device 20

FIG. 36 is a plan view showing an outline of a display device according to an embodiment of the present invention. As is shown in FIG. 36, the display device 20 includes an array substrate 300, a seal portion 310, a counter substrate 320, a flexible printed circuit substrate 330 (FPC 330), and an IC chip 340. The array substrate 300 and the counter substrate 320 are bonded together by the seal portion 310. A plurality of pixel circuits 301 is arranged in a matrix in a liquid crystal region 22 surrounded by the seal portion 310. The liquid crystal region 22 is a region overlapping a liquid crystal element 311, which will be described later, in a plan view.

A seal region 24 where the seal portion 310 is arranged is a region surrounding the liquid crystal region 22. The FPC 330 is arranged in a terminal region 26. The terminal region 26 is a region where the array substrate 300 is exposed from the counter substrate 320 and is arranged outside the seal region 24. Outside the seal region 24 means regions outside the region where the seal portion 310 is arranged and the region surrounded by the seal portion 310. The IC chip 340 is arranged on the FPC 330. The IC chip 340 supplies a signal for driving each pixel circuit 301.

### Circuit Configuration of Display Device 20

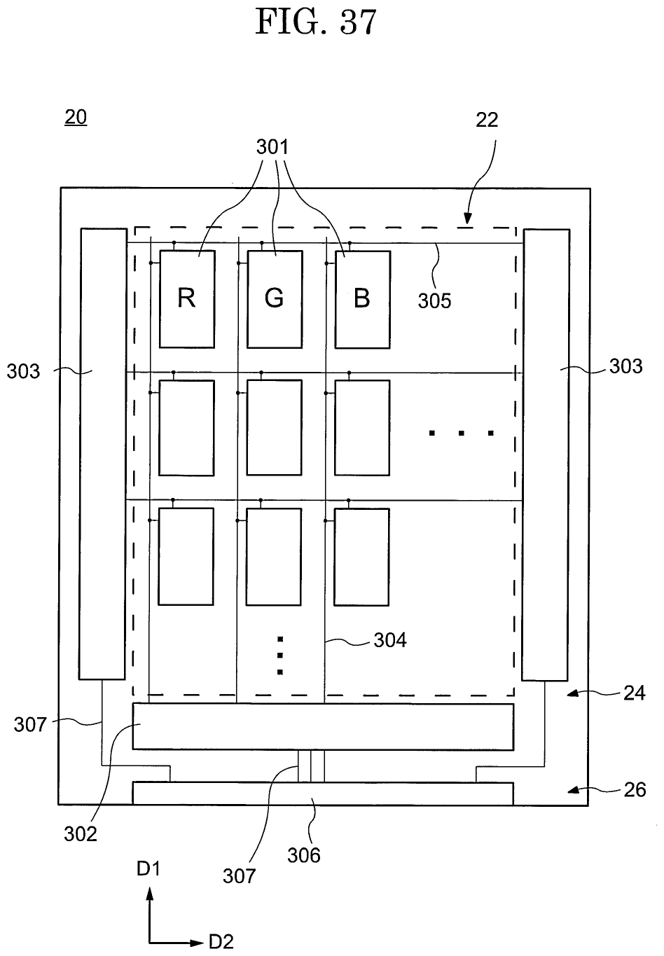

FIG. 37 is a block diagram showing a circuit configuration of a display device according to an embodiment of the present invention. As is shown in FIG. 37, a source driver circuit 302 is arranged at a position adjacent to the liquid crystal region 22 where the pixel circuit 301 is arranged in the first direction D1 (column direction), and a gate driver circuit 303 is arranged at a position adjacent to the liquid crystal region 22 in the second direction D2 (row direction). The source driver circuit 302 and the gate driver circuit 303 are arranged in the seal region 24 described above. However, the region where the source driver circuit 302 and the gate driver circuit 303 are arranged is not limited to the seal region 24. The source driver circuit 302 and the gate driver circuit 303 may be arranged in any region outside the region where the pixel circuit 301 is arranged.

A source wiring 304 extends from the source driver circuit 302 in the first direction D1 and is connected to the plurality of pixel circuits 301 arranged in the first direction D1. A gate wiring 305 extends from the gate driver circuit 303 in the second direction D2 and is connected to the plurality of pixel circuits 301 arranged in the second direction D2.

A terminal portion 306 is arranged in the terminal region 26. The terminal portion 306 and the source driver circuit 302 are connected by a connection wiring 307. Similarly, the terminal portion 306 and the gate driver circuit 303 are connected by the connection wiring 307. By connecting the FPC 330 to the terminal portion 306, an external device which is connected to the FPC 330 and the display device 20 are connected, and a signal from the external device drives each pixel circuit 301 arranged in the display device 20.

The semiconductor device 10 shown in the first embodiment and the second embodiment is used as a transistor included in the pixel circuit 301, the source driver circuit 302, and the gate driver circuit 303.

### Pixel Circuit 301 of Display Device 20

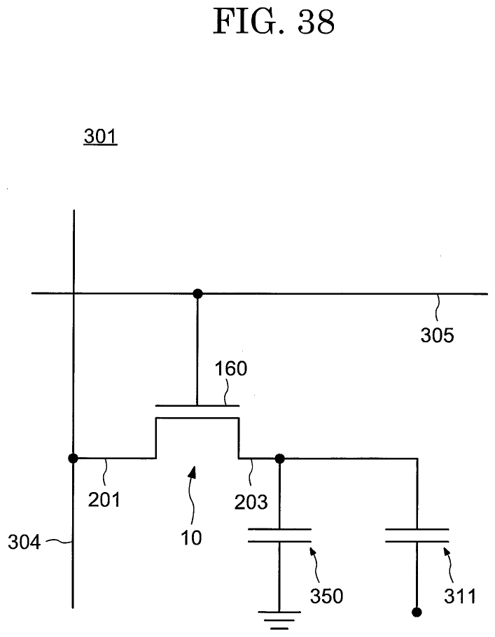

FIG. 38 is a circuit diagram showing a pixel circuit of a display device according to an embodiment of the present invention. As is shown in FIG. 38, the pixel circuit 301 includes elements such as the semiconductor device 10, a storage capacitor 350, and the liquid crystal element 311. The semiconductor device 10 has the gate electrode 160, the source electrode 201, and the drain electrode 203. The gate electrode 160 is connected to the gate wiring 305. The source electrode 201 is connected to the source wiring 304. The drain electrode 203 is connected to the storage capacitor 350 and the liquid crystal element 311. In the present embodiment, although an electrode indicated by 201 is referred to as a source electrode and an electrode indicated by 203 is referred to as a drain electrode for the convenience of explanation, the electrode indicated by 201 may function as a drain electrode and the electrode indicated by 203 may function as a source electrode.

### Cross-Section of Display device 20

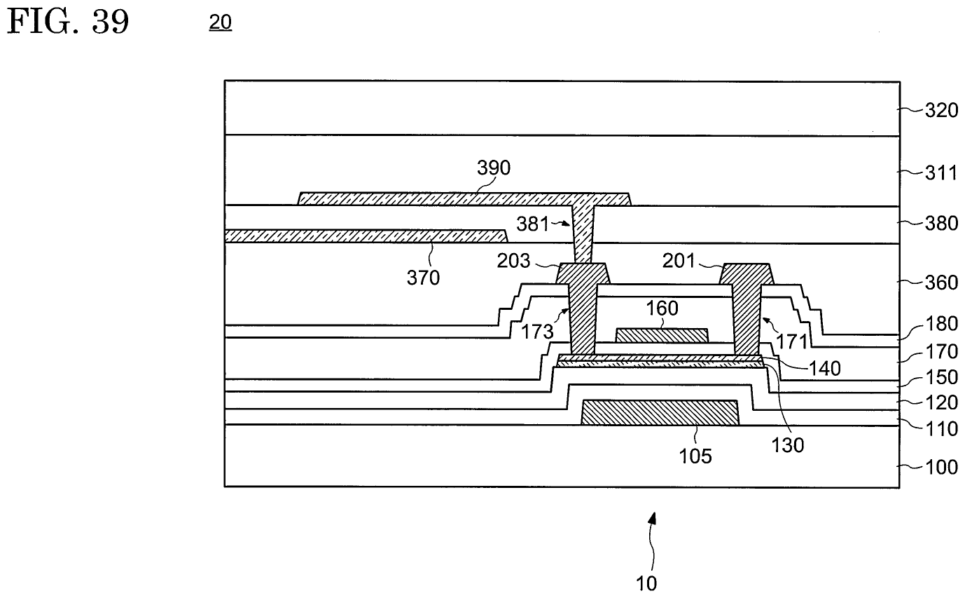

FIG. 39 is a cross-sectional view of a display device according to an embodiment of the present invention. As shown in FIG. 39, the display device 20 is a display device in which the semiconductor device 10 is used. In the present embodiment, although a configuration in which the semiconductor device 10 is used for the pixel circuit 301 is exemplified, the semiconductor device 10 may be used for a peripheral circuit including the source driver circuit 302 and the gate driver circuit 303. In the following description, since the configuration of the semiconductor device 10 is the same as that of the semiconductor device 10 shown in FIG. 1, the description thereof will be omitted.

An insulating layer 360 is arranged on the source electrode 201 and the drain electrode 203. A common electrode 370 arranged in common for the plurality of pixels is arranged on the insulating layer 360. An insulating layer 380 is arranged on the common electrode 370. An opening 381 is arranged in the insulating layers 360 and 380. A pixel electrode 390 is arranged on the insulating layer 380 and within the opening 381. The pixel electrode 390 is connected to the drain electrode 203.

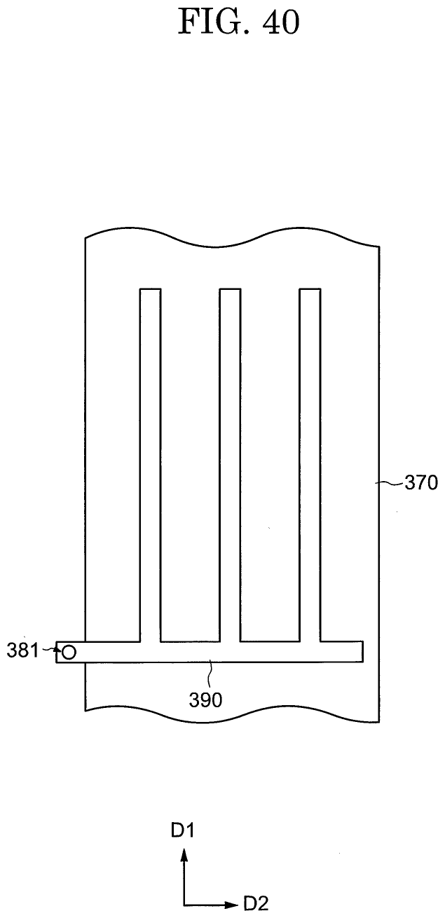

FIG. 40 is a plan view of a pixel electrode and a common electrode of a display device according to an embodiment of the present invention. As shown in FIG. 40, the common electrode 370 has an overlapping region overlapping the pixel electrode 390 in a plan view, and a non-overlapping region not overlapping the pixel electrode 390. When a voltage is supplied between the pixel electrode 390 and the common electrode 370, a horizontal electric field is formed from the pixel electrode 390 in the overlapping region toward the common electrode 370 in the non-overlapping region. The gradation of the pixel is determined by the operation of liquid crystal molecules included in the liquid crystal element 311 by the horizontal electric field.

### Fourth Embodiment

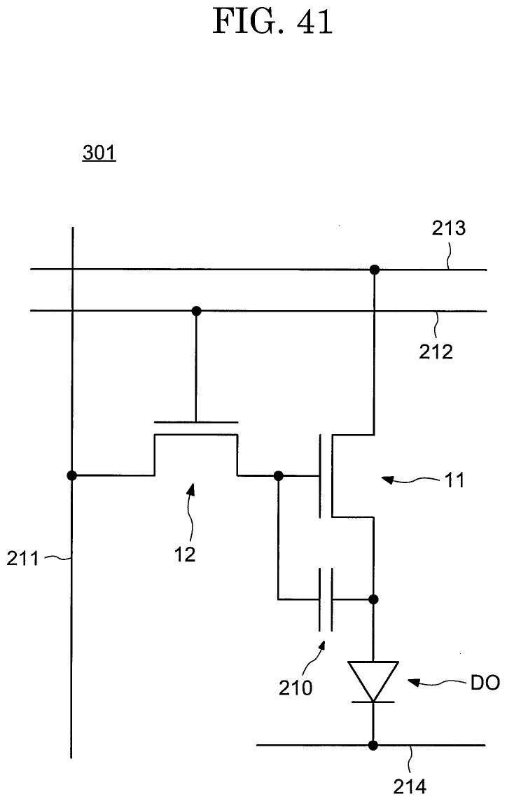

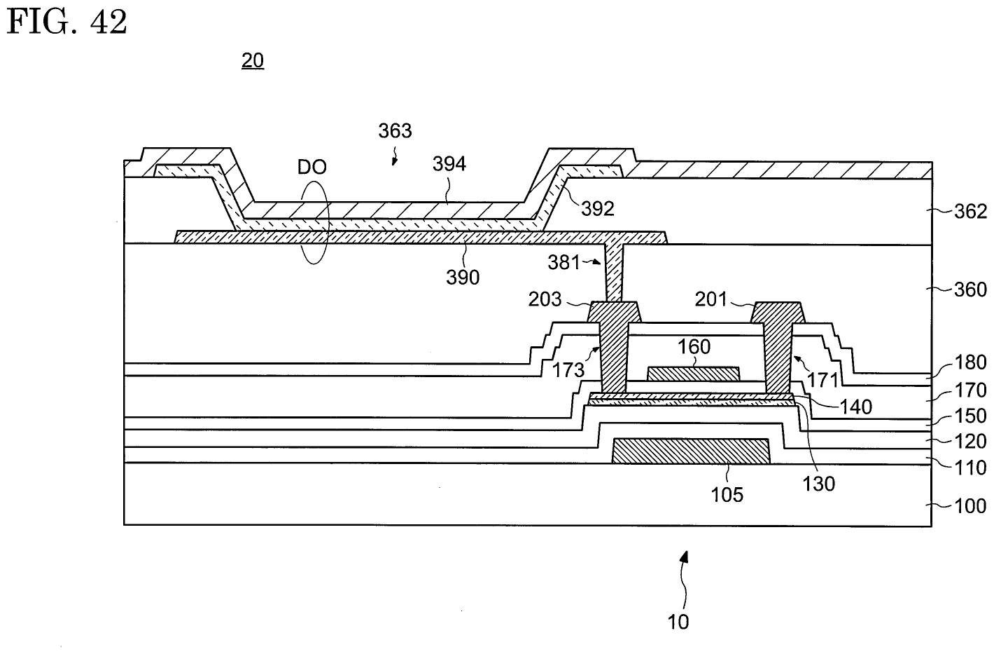

A display device using a semiconductor device according to an embodiment of the present invention will be explained with reference to FIG. 41 and FIG. 42. In the present embodiment, a configuration in which the semiconductor device 10 explained in the first embodiment and the second embodiment is applied to a circuit of an organic EL display device will be described. Since the outline and the circuit configuration of the display device 20 are the same as those shown in FIG. 36 and FIG. 37, the description thereof will be omitted.

### Pixel Circuit 301 of Display Device 20

FIG. 41 is a circuit diagram showing a pixel circuit of a display device according to an embodiment of the present invention. As shown in FIG. 41, the pixel circuit 301 includes elements such as a drive transistor 11, a selection transistor 12, a storage capacitor 210, and a light-emitting element DO. The drive transistor 11 and the selection transistor 12 have the same configuration as the semiconductor device 10. The source electrode of the selection transistor 12 is connected to a signal line 211, and the gate electrode of the selection transistor 12 is connected to a gate line 212. The source electrode of the drive transistor 11 is connected to an anode power line 213, and the drain electrode of the drive transistor 11 is connected to one end of the light-emitting element DO. The other end of the light-emitting element DO is connected to a cathode power line 214. The gate electrode of the drive transistor 11 is connected to the drain electrode of the selection transistor 12. The storage capacitor 210 is connected to the gate electrode and the drain electrode of the drive transistor 11. A gradation signal for determining the light-emitting intensity of the light-emitting element DO is supplied to the signal line 211. A signal for selecting a pixel row in which the gradation signal described above is written is supplied to the gate line 212.

### Cross-Sectional Structure of Display Device 20

FIG. 42 is a cross-sectional diagram of a display device according to an embodiment of the present invention. Although the configuration of the display device 20 shown in FIG. 42 is similar to the display device 20 shown in FIG. 39, the configuration above the insulating layer 360 of the display device 20 in FIG. 42 is different from the structure above the insulating layer 360 of the display device 20 in FIG. 39. Hereinafter, in the configuration of the display device 20 in FIG. 42, descriptions of the same configuration as the display device 20 in FIG. 39 are omitted, and differences between the two will be explained.

As shown in FIG. 42, the display device 20 has the pixel electrode 390, a light-emitting layer 392, and a common electrode 394 (the light-emitting element DO) above the insulating layer 360. The pixel electrode 390 is arranged above the insulating layer 360 and inside the opening 381. An insulating layer 362 is arranged above the pixel electrode 390. An opening 363 is arranged in the insulating layer 362. The opening 363 corresponds to a light-emitting region. That is, the insulating layer 362 defines a pixel. The light-emitting layer 392 and the common electrode 394 are arranged above the pixel electrode 390 exposed by the opening 363. The pixel electrode 390 and the light-emitting layer 392 are individually arranged for each pixel. On the other hand, the common electrode 394 is arranged in common for the plurality of pixels. Different materials are used for the light-emitting layer 392 depending on the display color of the pixel.

In the third embodiment and the fourth embodiment, although the configuration in which the semiconductor device explained in the first embodiment and the second embodiment was applied to a liquid crystal display device and an organic EL display device was exemplified, the semiconductor device may be applied to display devices (for example, a self-luminous display device or an electronic paper display device other than an organic EL display device) other than these display devices. In addition, the semiconductor device described above can be applied without any particular limitation from a small sized display device to a large sized display device.

### EXAMPLES

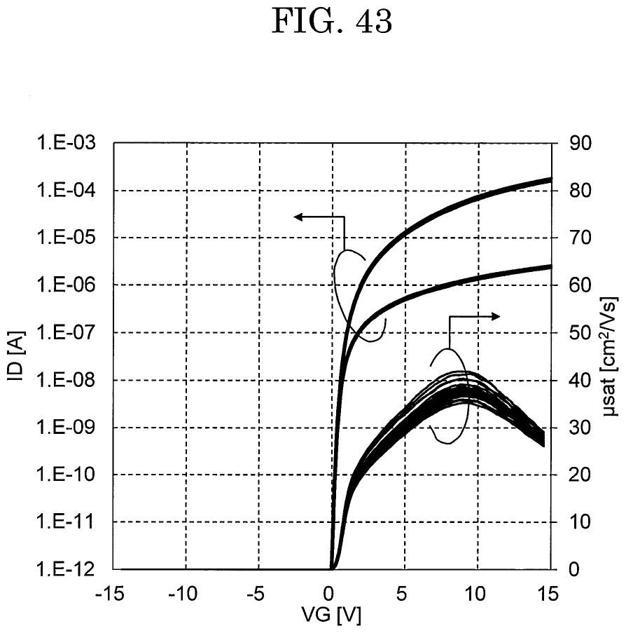

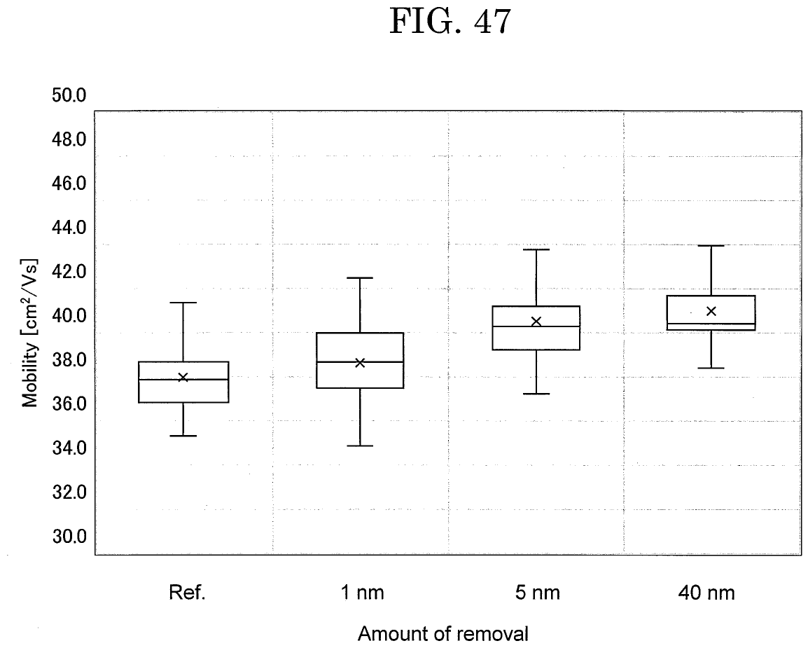

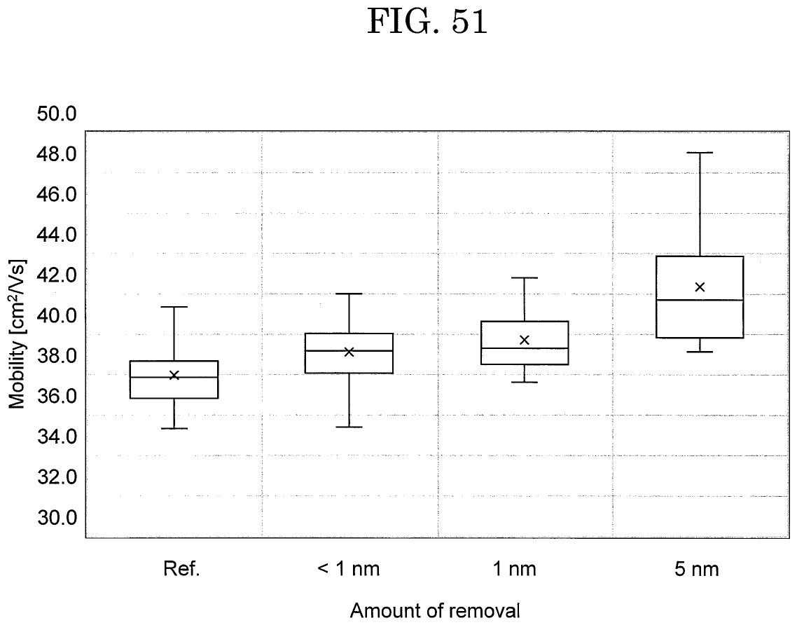

In this example, the effect of the planarization process on the surface of the aluminum-based oxide metal layer is explained with reference to FIG. 43 to FIG. 51. FIG. 43 to FIG. 46 and FIG. 48 to FIG. 50 show the electrical characteristics of the semiconductor device. FIG. 47 and FIG. 51 are box plots representing the field-effect mobility of the semiconductor device.

### Relationship between Flatness of Aluminum Oxide and Electrical Characteristics of Semiconductor Device

In this example, the semiconductor device was formed according to the sequence diagram of the manufacturing method of the semiconductor device 10 shown in FIG. 24. In this example, aluminum oxide was used as the metal oxide with aluminum as the main component.

### Planarization Process of Aluminum Oxide

Conditions for planarization process of aluminum oxide are as follows:
Substrate: glass substrate
Thickness of aluminum oxide at deposition: 10 nm, 11 nm, 15 nm, and 50 nm
Condition 1 of planarization process (developer solution (TMAH)): 1 nm, 5 nm, and 40 nm
Condition 2 of planarization process (Ar gas): less than 1 nm, 1 nm, and 5 nm

The thickness of the aluminum oxide at deposition is set to be 10 nm in both cases by performing the planarization process. When the thickness at deposition is 50 nm, the thickness is reduced to 10 nm by removing 40 nm through the planarization process. When the thickness at deposition is 15 nm, the thickness is reduced to 10 nm by removing 5 nm through the planarization process. When the thickness is 10 nm at deposition, the thickness is reduced 10 nm by removing less than 1 nm by performing the planarization process.

### Initial Characteristics

The measurement conditions for the electrical characteristics shown in FIG. 43 to FIG. 46 and FIG. 48 to FIG. 50 are as follows:
Channel region CH size: W/L=4.5 μm/3.0 μm
Source-drain voltage: 0.1 V or 10 V
Gate voltage: −15V to +15V
Measurement environment: Room temperature, dark room
Measurement point: 26 points

First, the results of the planarization process of the aluminum oxide under Condition 1 (developer solution (TMAH)) of the planarization process are described.

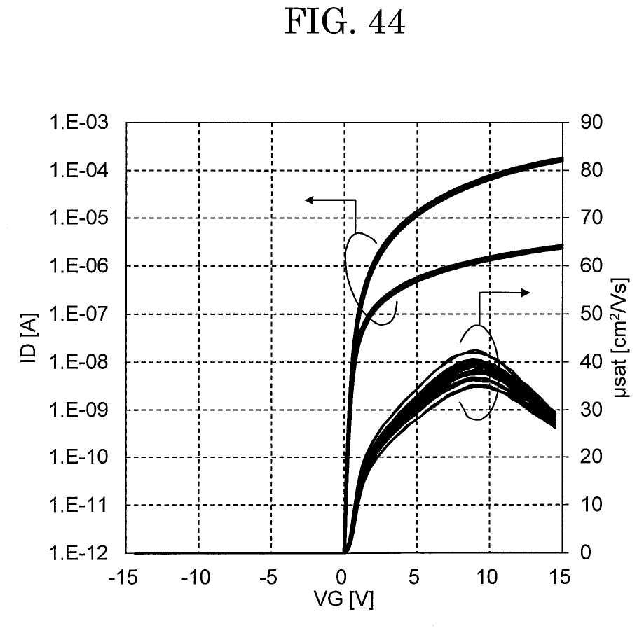

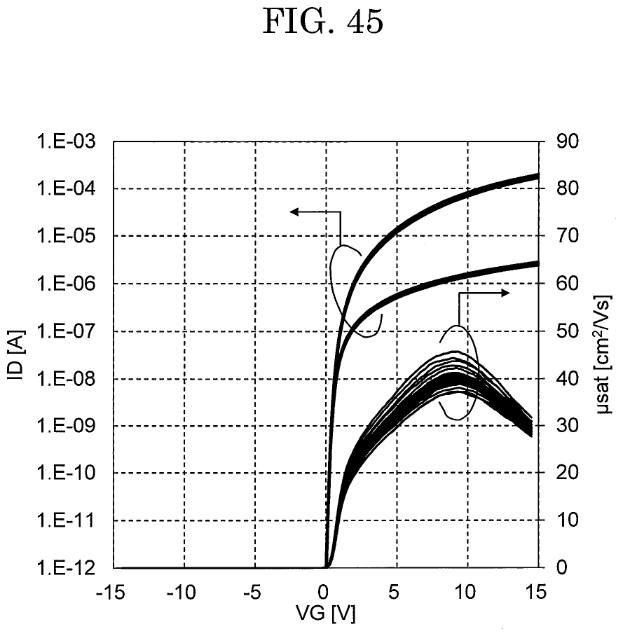

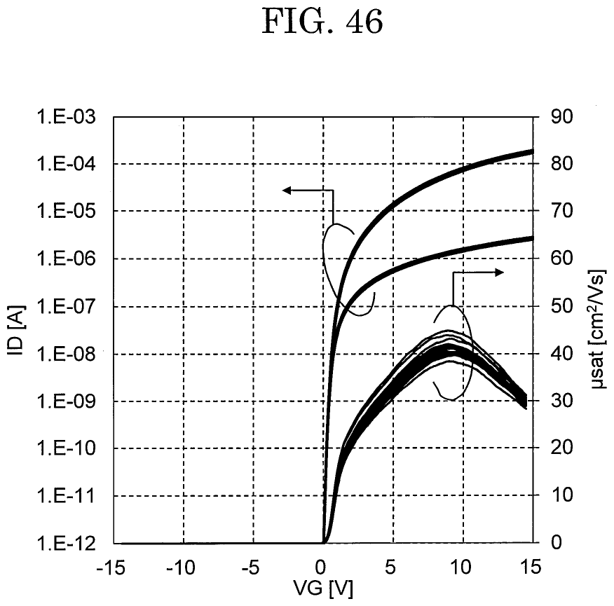

FIG. 43 shows the electrical characteristics (Id-Vg characteristics) and mobility of the semiconductor device without the planarization process. FIG. 44 shows the electrical characteristics (Id-Vg characteristics) and mobility of the semiconductor devices in which the surface of the aluminum oxide layer is removed by 1 nm through the planarization process. FIG. 45 shows the electrical characteristics (Id-Vg characteristics) and mobility of the semiconductor device in which the surface of the aluminum oxide layer is removed 5 nm by the planarization process. FIG. 46 shows the electrical characteristics (Id-Vg characteristics) and mobility of the semiconductor device in which the surface of the aluminum oxide layer is removed by 40 nm by the planarization process. All of FIG. 43 to FIG. 46 are the results of measuring the electrical characteristics at 26 locations within the substrate plane.

As shown by the arrows in the graphs in FIG. 43 to FIG. 46, the vertical axis for drain current (Id) is shown on the left side of the graph, and the vertical axis for mobility calculated from the drain current is shown on the right side of the graph.

The average threshold voltage in the substrate plane of the electrical characteristics are shown in FIG. 43 is 0.51 V, the average threshold voltage in the substrate plane of the electrical characteristics are shown in FIG. 44 is 0.52 V, the average threshold voltage in the substrate plane of the electrical characteristics are shown in FIG. 45 is 0.53 V, and the average threshold voltage in the substrate plane of the electrical characteristics are shown in FIG. 46 is 0.51V. As shown in FIG. 43 to FIG. 46, the electrical characteristics of the semiconductor devices exhibit the so-called normally-off characteristics, in which the drain current Id begins to flow at a gate voltage Vg higher than 0 V.

FIG. 47 shows box plots representing the distribution of mobility within the substrate plane (26 points) for each of the semiconductor devices shown in FIG. 43 to FIG. 46. In FIG. 47, the horizontal axis is for Ref. (untreated), 1 nm, 5 nm, and 40 nm removed, and the vertical axis is field effect mobility (cm²/Vs).

As shown in FIG. 47, the average value of mobility in the untreated case is 38.0 cm²/Vs, and the average value of mobility when 1 nm of the surface of the aluminum oxide layer is removed is 38.6 cm²/Vs. The average value of the mobility when 5 nm of the surface of the aluminum oxide layer is removed is 40.5 cm²/Vs, and the average value of the mobility when 5 nm of the surface of the aluminum oxide layer is removed is 41.0 cm²/Vs. FIG. 47 shows that the average value of the field-effect mobility of the semiconductor device tends to increase with the amount of the aluminum oxide layer removed by the wet etching process. The removal of 5 nm or more of the aluminum oxide layer indicates that the average value of mobility exceeds 40 cm²/Vs.

Next, the results of the planarization process of the aluminum oxide under Condition 2 (Ar gas) of the planarization process are described.

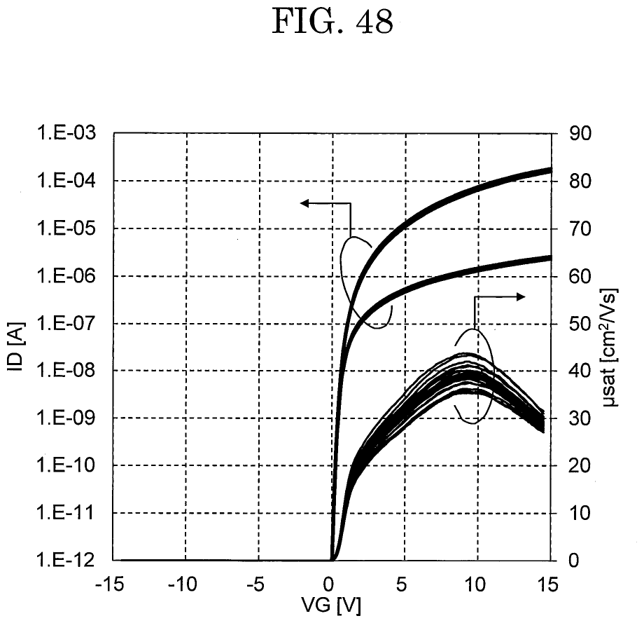

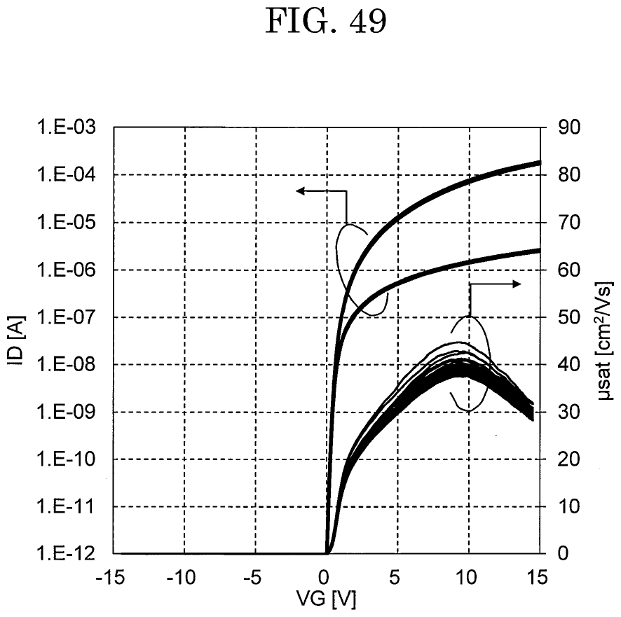

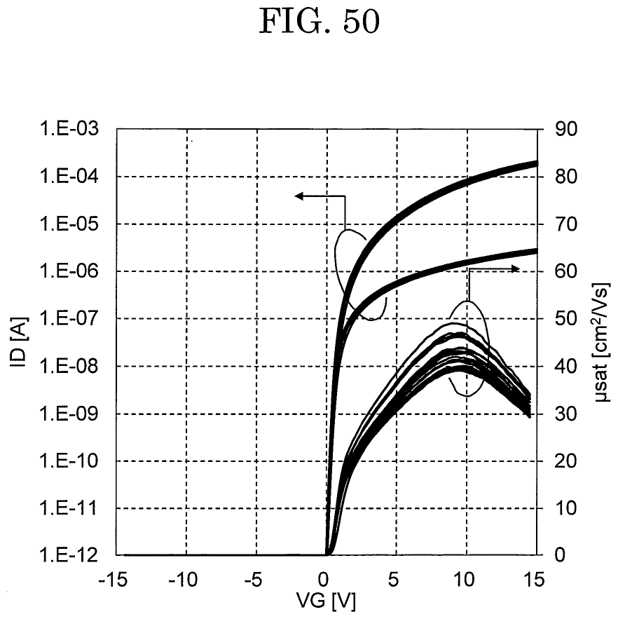

FIG. 48 shows the electrical characteristics (Id-Vg characteristics) and mobility of a semiconductor device in which less than 1 nm of the surface of the aluminum oxide layer is removed by the planarization process. FIG. 49 shows the electrical characteristics (Id-Vg characteristics) and mobility of semiconductor devices in which the surface of the aluminum oxide layer is removed 1 nm by the planarization process. FIG. 50 shows the electrical characteristics (Id-Vg characteristics) and mobility of the semiconductor device in which the surface of the aluminum oxide layer is removed 5 nm by the planarization process. All of FIG. 48 through FIG. 50 are the results of measuring the electrical characteristics at 26 points within the substrate plane.

As indicated by the arrows in the graphs in FIG. 48 FIG. 50, the vertical axis for drain current (Id) is shown on the left side of the graph, and the vertical axis for mobility calculated from the drain current is shown on the right side of the graph.

The average value of the threshold voltage in the substrate plane of the electrical characteristics is shown in FIG. 48 is 0.55 V, the average value of the threshold voltage in the substrate plane of the electrical characteristics is shown in FIG. 49 is 0.53 V, and the average value of the threshold voltage in the substrate plane of the electrical characteristics is shown in FIG. 50 is 0.55 V. As shown in FIG. 48 to FIG. 50, the electrical characteristics of the semiconductor devices exhibit the so-called normally-off characteristics, in which the drain current Id begins to flow at a gate voltage Vg higher than 0V.

FIG. 51 shows box plots representing the distribution of mobility within the substrate plane (26 points) for each of the semiconductor devices shown in FIG. 43 and FIG. 48 to FIG. 50. In FIG. 51, the horizontal axis is Ref. (untreated), less than 1 nm, 1 nm, and 5 nm removed, and the vertical axis is the field effect mobility (cm²/Vs).

As shown in FIG. 51, the average value of the mobility in the untreated case is 38.0 cm²/Vs, and the average value of the mobility when the surface of the aluminum oxide layer is removed by less than 1 nm is 39.1 cm²/Vs. The average value of the mobility when 1 nm of the surface of the aluminum oxide layer is removed is 39.7 cm²/Vs, and the average value of the mobility when 5 nm of the surface of the aluminum oxide layer is removed is 42.4 cm²/Vs. It can be seen that the average value of the field effect mobility of the semiconductor device tends to increase with the amount of the aluminum oxide layer removed by the plasma process. It was shown that the average value of the mobility exceeds 40 cm²/Vs when the aluminum oxide layer is removed by more than 5 nm.

As explained above, it was shown that the average value of the mobility of the semiconductor device 10 exceeds 40 cm²/Vs by removing 5 nm or more of the aluminum oxide in Conditions 1 and 2 of the planarization process.

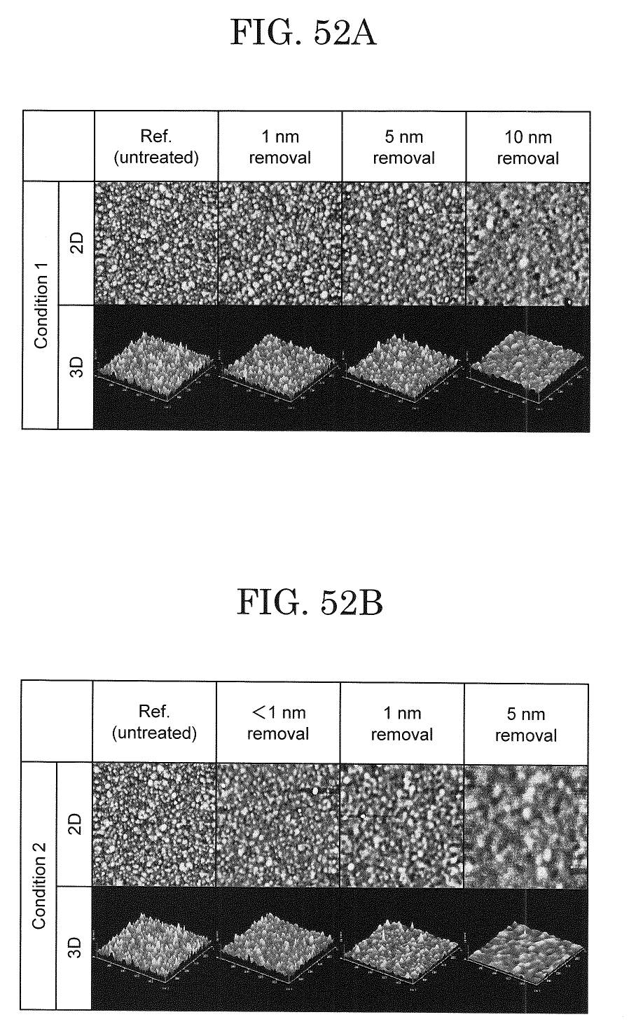

Next, the correlation between the arithmetic mean roughness Ra after planarization process on the surface of aluminum oxide and the field effect mobility u is verified, and the results are explained with reference to FIG. 52A to FIG. 55.

First, the arithmetic mean roughness Ra and the root mean square roughness Rq after forming an aluminum oxide layer on the substrate and performing the planarization process on the aluminum oxide layer are explained.

### Planarization Process of Aluminum Oxide

Condition 2 for planarization process of aluminum oxide are as follows:
Substrate: Glass substrate
Thickness of aluminum oxide film: 10 nm, 11 nm, 15 nm, and 50 nm
Planarization process Condition 1 (developer (TMAH)): 1 nm, 5 nm, and 40 nm
Planarization process Condition 2 (Ar gas): less than 1 nm, 1 nm, and 5 nm

The thickness of the aluminum oxide at the deposition is set to be 10 nm in all cases by the planarization process. When the thickness at the deposition is 50 nm, the thickness is reduced to 10 nm by removing 40 nm through the planarization process. When the thickness at the deposition is 15 nm, the thickness is reduced to 10 nm by removing 5 nm through the planarization process. When the thickness at the deposition is 10 nm, the thickness is reduced to 10 nm by removing less than 1 nm through the planarization process.

FIG. 52A is an AFM image of the surface of the metal oxide layer after the planarization process according to Condition 1, and FIG. 52B is an AFM image of the metal oxide layer after the planarization process according to Condition 2. The observed region of the AFM images of the surface of the metal oxide layer shown in FIG. 52A and FIG. 52B is 1000 nm square and 10 nm high (fixed).

Roughness curves were obtained from the AFM images shown in FIG. 52A and FIG. 52B. Based on the roughness curves, the arithmetic mean roughness (Ra) and root the mean square roughness (Rq) were obtained as roughness curve parameters.

TABLE 1

| | Amount of removal (nm) | Ra (nm) | Rq (nm) |
|---|---|---|---|
| Ref. | 0 | 1.035 | 1.344 |
| Condition 1 | 1 | 0.908 | 1.168 |
| | 5 | 0.819 | 1.104 |
| | 40 | 0.708 | 0.9673 |
| Condition 2 | <1 | 0.839 | 1.219 |
| | 1 | 0.591 | 0.7792 |
| | 5 | 0.346 | 0.4541 |

As shown in Table 1, both the arithmetic mean roughness (Ra) and the root mean square roughness (Rq) were found to decrease with the amount of surface removal of the aluminum oxide layer in both Condition 1 and Condition 2.

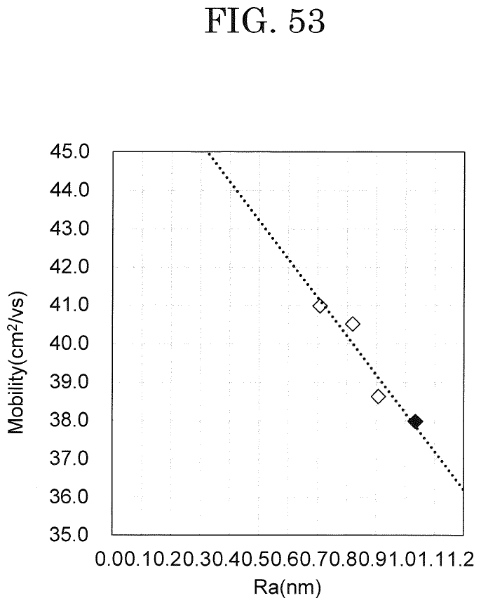

Next, the correlation between the arithmetic mean roughness Ra of the surface of the aluminum oxide layer and the field-effect mobility μ of the semiconductor device was verified, and the results are explained with reference to FIG. 53 to FIG. 55.

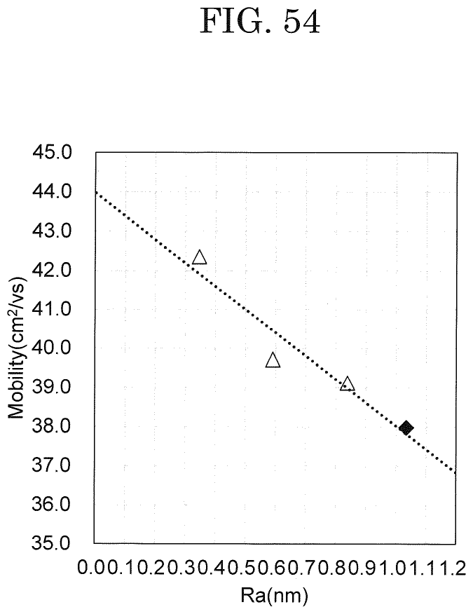

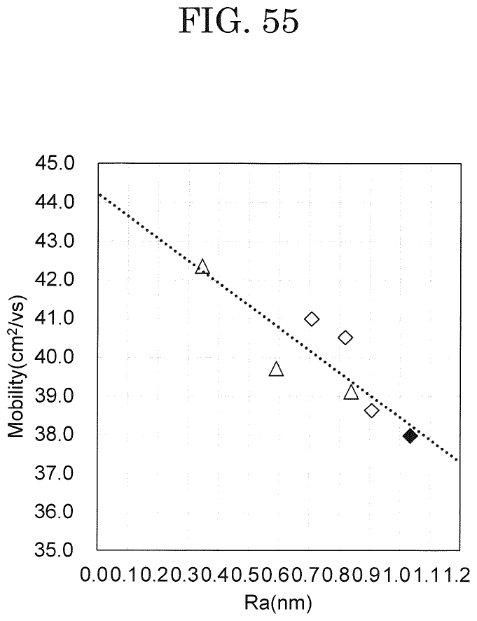

FIG. 53 shows the dependence of the arithmetic mean roughness (Ra) of the aluminum oxide layer by the planarization process (Condition 1) and the field-effect mobility of the semiconductor device. FIG. 54 shows the dependence of the arithmetic mean roughness (Ra) of the aluminum oxide layer by the planarization process (Condition 2) and the field-effect mobility of the semiconductor device. FIG. 55 shows the dependence of the arithmetic mean roughness (Ra) of the aluminum oxide layer by the planarization process (Conditions 1 and 2) and the field-effect mobility of the semiconductor device.

The arithmetic mean roughness Ra shown in FIG. 53 corresponds to the results when the surface of the aluminum oxide layer is removed by 1 nm, 5 nm, and 40 nm according to Condition 1 in Table 1 and Ref. (untreated). The field-effect mobility u corresponds to the results of removing 1 nm, 5 nm, and 40 nm of the surface of the aluminum oxide layer shown in FIG. 47 and the case of Ref.

The arithmetic mean roughness Ra shown in FIG. 54, corresponds to the results of removing less than 1 nm, 1 nm, and 5 nm from the surface of the aluminum oxide layer according to Condition 2 shown in Table 1, and the case of Ref. (untreated). The field effect mobility u corresponds to the results for the case where less than 1 nm, 1 nm, and 5 nm are removed from the surface of the aluminum oxide layer shown in FIG. 51, and for the case of Ref. (untreated).

FIG. 55 shows the dependence of the arithmetic mean roughness (Ra) of the aluminum oxide layer by the planarization process (Conditions 1 and 2) and the field effect mobility of the semiconductor device. FIG. 55 is a graph summarizing the results shown in FIG. 53 and FIG. 54.

The approximate line shown in FIG. 53 was confirmed to be y=−10.033x+48.23. In FIG. 53, it was confirmed that Ra≤0.80 is preferable to achieve a field effect mobility μ of 40 cm²/Vs or more. It was also confirmed that the approximate line shown in FIG. 54 is y=−5.9584+43.978. In FIG. 54, it was confirmed that Ra≤0.67 is preferable to obtain a field effect mobility μ of 40 cm²/Vs. It was also confirmed that the approximate line shown in FIG. 55 is y=−5.7697x+44.223. In FIG. 55, it was confirmed that Ra≤0.73 is desirable for the field effect mobility μ to be 40 cm²/Vs or higher. Here, y represents the field effect mobility, and x represents the arithmetic mean roughness.

### Effect of Planarization Process of Surface of Metal Oxide Layer on Electrical Characteristics of Semiconductor Device

As shown in FIG. 53 to FIG. 55, it was confirmed that the arithmetic mean roughness (Ra) of the surface of the aluminum oxide layer was reduced and the field-effect mobility μ was improved by the planarization process using both Condition 1 and Condition 2. It was also confirmed that the smaller the arithmetic mean roughness (Ra) of the surface of the aluminum oxide layer, the higher the field-effect mobility u becomes. In other words, by performing a planarization process on the surface of the aluminum oxide layer, the flatness of the surface of the aluminum oxide layer is improved, and by forming a oxide semiconductor layer on thereon and performing a heat treatment, the random direction of crystal growth can be suppressed and the direction and speed of crystal growth can be aligned. This allows the gate electrode voltage of the semiconductor device to be controlled. This is thought to have improved field-effect mobility by reducing factors that inhibit the movement of electrons within the oxide semiconductor layer when a voltage is applied to the gate electrode of the semiconductor device.

Each of the embodiments described above as an embodiment of the present invention can be appropriately combined and implemented as long as no contradiction is caused. In addition, the addition, deletion, or design change of components, or the addition, deletion, or condition change of processes as appropriate by those skilled in the art based on a semiconductor device and a display device of each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A method for manufacturing a semiconductor device, the method comprising steps of:
forming a first metal oxide layer containing aluminium as a main component above an insulating surface;
performing a planarization process on a surface of the first metal oxide layer;
forming an oxide semiconductor layer on the insulating surface on which the planarization process is performed;
forming a gate insulating layer above the oxide semiconductor layer; and
forming a gate electrode facing the oxide semiconductor layer above the gate insulating layer.

2. The method according to claim 1, wherein
the planarization process makes an arithmetic mean roughness Ra of a surface of the first metal oxide layer less than 0.80 nm.

3. The method according to claim 1, further comprising:
the planarization process removes at least 5 nm or more from the surface of the first metal oxide layer.

4. The method according to claim 1, wherein
the planarization process is performed by wet etching using tetramethylammonium hydroxide, potassium hydroxide, or a mixed acid containing phosphoric acid, nitric acid, and acetic acid.

5. The method according to claim 1, wherein
the planarization process is performed by a plasma process using an inert gas or halogen gas.

6. The method according to claim 1, wherein
a thickness of the first metal oxide layer after the planarization process is 1 nm or more and 20 nm or less.

7. The method according to claim 1, further comprising the steps of:
forming a second metal oxide layer on the gate insulating layer after forming the gate insulating layer;
performing an annealing process with the second metal oxide layer formed on the gate insulating layer; and
removing the second metal oxide layer after the annealing process.

8. A semiconductor device comprising:
a metal oxide layer containing aluminium as a main component above an insulating surface;
an oxide semiconductor layer on the metal oxide layer;
a gate electrode facing the oxide semiconductor layer; and
a gate insulating layer between the oxide semiconductor layer and the gate electrode;
wherein a relationship between an arithmetic mean roughness Ra (nm) of a surface of the metal oxide layer and a field effect mobility μ (cm²/Vs) is expressed by the following formula.
μ=−10.033Ra+48.23
(Where the arithmetic mean roughness Ra≤0.80 nm).

9. The semiconductor device according to claim 8, wherein
a thickness of the metal oxide layer is 1 nm or more and 20 nm or less.

10. The semiconductor device according to claim 8, wherein
the metal oxide layer has a barrier property against oxygen and hydrogen.

11. The semiconductor device according to claim 8, wherein
the oxide semiconductor layer contains two or more metals including indium, and a ratio of indium in the two or more metals is 50% or more.

12. The semiconductor device according to claim 8, wherein
the oxide semiconductor layer is a crystalline oxide semiconductor layer.

13. The semiconductor device according to claim 8, wherein
a field effect mobility is greater than 40 cm²/Vs.
